(19) United States
(12) Patent Application Publication
(10) Pub. No.: US 2026/0357052 A1
(43) Pub. Date: Nov. 12, 2026

(54) RESIN COMPOSITION, TEMPORARY FIXING MATERIAL, AND MANUFACTURING METHOD FOR ELECTRONIC COMPONENT

(71) Applicant: SEKISUI CHEMICAL CO., LTD., Osaka (JP)

(72) Inventors: Yuki NISHIUMI, Osaka (JP); Toshio TAKAHASHI, Osaka (JP); Tokushige SHICHIRI, Osaka (JP); Satoshi HAYASHI, Osaka (JP); Hisatoshi OKAYAMA, Osaka (JP); Izumi DAIDO, Osaka (JP); Chieko MORI, Osaka (JP)

(73) Assignee: SEKISUI CHEMICAL CO., LTD., Osaka (JP)

(21) Appl. No.: 19/112,445

(22) PCT Filed: Sep. 21, 2023
(86) PCT No.: PCT/JP2023/034182

§ 371 Date: Mar. 17, 2025

(30) Foreign Application Priority Data
Sep. 21, 2022 (JP) 2022-150426

(51) Int. Cl. C08L 33/10

(52) U.S. Cl. CPC C08L 33/10; C08L 2203/20

(57) ABSTRACT

The present invention aims to provide a resin composition that can reduce the occurrence of voids and partial detachment during heat treatment and is easily separable after the heat treatment. The present invention also aims to provide a temporary fixing material containing the resin composition and a method for producing an electronic component using the temporary fixing material. The present invention relates to a resin composition containing: a resin having an imide skeleton in a backbone repeating unit; and a (meth)acrylic copolymer.

### TECHNICAL FIELD

The present invention relates to a resin composition. The present invention also relates to a temporary fixing material containing the resin composition and a method for producing an electronic component using the temporary fixing material.

### BACKGROUND ART

During the processing of electronic components such as semiconductors, electronic components are fixed to supports using a temporary fixing material containing a resin composition or protected by adhesive tapes produced using a temporary fixing material that includes an adhesive layer containing a resin composition, attached to the electronic components for easier handling or less breakage of the electronic components. In the case where a thick wafer cut out from a highly pure silicon single crystal is ground to a thin wafer having a predetermined thickness, for example, the thick wafer is attached to a support using a temporary fixing material.

Temporary fixing materials thus used with electronic components are required to have high adhesiveness to firmly fix electronic components during the processing, as well as separability from the electronic components without causing damage to the electronic components after the processing (hereafter, also referred to as “high adhesion and easy separation”).

As a means for achieving high adhesion and easy separation, Patent Literature 1, for example, discloses an adhesive sheet produced using an adhesive in which to a side chain or main chain of a polymer is bonded a polyfunctional monomer or oligomer containing a radiation polymerizable functional group. The polymer is cured by irradiation with UV as it has the radiation polymerizable functional group, which allows lowering of the adhesion by irradiation with UV upon separation of the adhesive sheet, enabling separation without adhesive deposits.

### CITATION LIST

### Patent Literature

Patent Literature 1: JP H05-32946 A

### SUMMARY OF INVENTION

### Technical Problem

Recent higher-performance electronic components are subjected to various types of processing. For example, in the process of forming a thin metal film on a surface of an electronic component by sputtering, the processing is performed with heating at high temperature to form a thin metal film having higher electroconductivity.

However, heat treatment at high temperature performed on an electronic component protected using a conventional temporary fixing material may cause voids or partial detachment between the temporary fixing material and the support fixing the electronic component during the heating, and may also cause a rise in adhesion, leading to insufficient lowering of the adhesion or the generation of adhesive deposits upon separation.

Especially in recent years, polyimide resins, which are highly heat-resistant materials, have been used in many electronic components, and adherends having polyimide on their surfaces have been fixed to inorganic material supports (e.g., glass supports) and subjected to various types of processing. When subjected to heat treatment at high temperature, adherends having polyimide on their surfaces tend to suffer a greater rise in adhesion than adherends having inorganic material surfaces. The temporary fixing material used in such a case to protect the adherend needs to reduce a rise in adhesion to the adherend, while also reducing the occurrence of voids and partial detachment between the temporary fixing material and the support.

The present invention aims to provide a resin composition that can reduce the occurrence of voids and partial detachment during heat treatment and is easily separable after the heat treatment. The present invention also aims to provide a temporary fixing material containing the resin composition and a method for producing an electronic component using the temporary fixing material.

### Solution to Problem

The disclosure 1 relates to a resin composition containing: a resin having an imide skeleton in a backbone repeating unit; and a (meth)acrylic copolymer.

The disclosure 2 relates to the resin composition according to the disclosure 1, wherein the (meth)acrylic copolymer contains a structural unit derived from a branched alkyl (meth)acrylate.

The disclosure 3 relates to the resin composition according to the disclosure 2, wherein the (meth)acrylic copolymer contains the structural unit derived from a branched alkyl (meth)acrylate in a proportion of 20 mol % or greater and 80 mol % or less.

The disclosure 4 relates to the resin composition according to the disclosure 1, 2, or 3, wherein the (meth)acrylic copolymer contains a structural unit derived from an alkyl (meth)acrylate containing an alkyl group with a carbon number of 2 or greater and 7 or less and a structural unit derived from an alkyl (meth)acrylate containing an alkyl group with a carbon number of 8 or greater, and the (meth)acrylic copolymer contains the structural unit derived from an alkyl (meth)acrylate containing an alkyl group with a carbon number of 2 or greater and 7 or less in a proportion of 20 mol % or greater and 80 mol % or less.

The disclosure 5 relates to the resin composition according to the disclosure 1, 2, 3, or 4, wherein the (meth)acrylic copolymer contains no carbon-carbon double bond-containing reactive functional group.

The disclosure 6 relates to the resin composition according to the disclosure 1, 2, 3, 4, or 5, wherein the (meth)acrylic copolymer has a molecular weight of 2,000 or greater and 20,000 or less.

The disclosure 7 relates to the resin composition according to the disclosure 1, 2, 3, 4, 5, or 6, wherein the (meth)acrylic copolymer has a glass transition temperature of −70 °C or higher and −5 °C or lower.

The disclosure 8 relates to the resin composition according to the disclosure 1, 2, 3, 4, 5, 6, or 7, wherein the resin having an imide skeleton in a backbone repeating unit includes a resin containing no maleimide group and having an imide skeleton in a backbone repeating unit.

The disclosure 9 relates to the resin composition according to the disclosure 8, wherein the resin containing no maleimide group and having an imide skeleton in a backbone repeating unit has an aliphatic group derived from a dimer diamine.

The disclosure 10 relates to the resin composition according to the disclosure 1, 2, 3, 4, 5, 6, 7, 8, or 9, which is thermosetting or photocurable.

The disclosure 11 relates to the resin composition according to the disclosure 1, 2, 3, 4, 5, 6, 7, 8, 9, or 10, further containing a compound containing a maleimide group.

The disclosure 12 relates to the resin composition according to the disclosure 11, wherein the compound containing a maleimide group is a bismaleimide compound or a resin containing a maleimide group and having an imide skeleton in a backbone repeating unit.

The disclosure 13 relates to the resin composition according to the disclosure 12, containing, as the resin containing a maleimide group and having an imide skeleton in a backbone repeating unit, a resin containing a structural unit represented by the following formula (1) and having a functional group containing a maleimide group at least either at an end or in a side chain.

The disclosure 14 relates to the resin composition according to the disclosure 1, 2, 3, 4, 5, 6, 7, 8, 9, 10, 11, 12, or 13, further containing a polyfunctional monomer or oligomer containing two or more carbon-carbon double bond-containing reactive functional groups in a molecule and having a molecular weight of 5,000 or less.

The disclosure 15 relates to the resin composition according to the disclosure 14, wherein the (meth)acrylic copolymer is contained in an amount of 0.1 parts by mass or greater and 20 parts by mass or less relative to 100 parts by mass of a total of the resin having an imide skeleton in a backbone repeating unit and the polyfunctional monomer or oligomer.

The disclosure 16 relates to the resin composition according to the disclosure 1, 2, 3, 4, 5, 6, 7, 8, or 9, which is non-curable.

The disclosure 17 relates to the resin composition according to the disclosure 1, 2, 3, 4, 5, 6, 7, 8, 9, 10, 11, 12, 13, 14, 15, or 16, wherein the resin composition has a 10% weight loss temperature of 200 °C or higher.

The disclosure 18 relates to a temporary fixing material containing the resin composition according to the disclosure 1, 2, 3, 4, 5, 6, 7, 8, 9, 10, 11, 12, 13, 14, 15, 16, or 17.

The disclosure 19 relates to a temporary fixing material including an adhesive layer containing the resin composition according to the disclosure 1, 2, 3, 4, 5, 6, 7, 8, 9, 10, 11, 12, 13, 14, 15, 16, or 17.

The disclosure 20 relates to the temporary fixing material according to the disclosure 19, which is a tape-like material.

The disclosure 21 relates to the temporary fixing material according to the disclosure 18, 19, or 20, wherein the temporary fixing material has an initial adhesion to polyimide at 25 °C of 0.1 N/inch or greater and 1.5 N/inch or less.

The disclosure 22 relates to a method for producing an electronic component, the method including: a temporary fixing step of temporarily fixing an electronic component to the temporary fixing material according to the disclosure 18, 19, 20, or 21; a heat treatment step of heat-treating the electronic component; and a separation step of separating the electronic component from the temporary fixing material.

The disclosure 23 relates to the method for producing an electronic component according to the disclosure 22, further including, between the temporary fixing step and the heat treatment step, a curing step of curing the temporary fixing material.

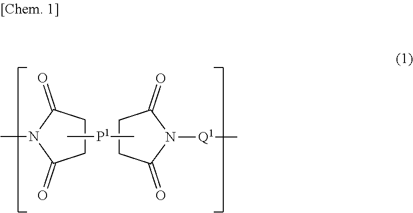

In the formula (1), P¹ represents an aromatic group and Q¹ represents a substituted or unsubstituted linear, branched, or cyclic aliphatic group.

The present invention is described in detail below.

The present inventors studied use of a resin composition containing a resin having an imide skeleton in a backbone repeating unit and a (meth)acrylic copolymer as a resin composition to be used in a temporary fixing material. As a result, they found out that a resin composition that can reduce the occurrence of voids and partial detachment during heat treatment and is easily separable after the heat treatment is obtainable. Thus, the present invention was completed.

The resin composition of the present invention contains a (meth)acrylic copolymer. The (meth)acrylic copolymer serves as a surface modifier. The resin composition of the present invention, which contains a combination of the (meth)acrylic copolymer and a later-described resin having an imide skeleton in a backbone repeating unit, can reduce the occurrence of voids and partial detachment during heat treatment and is easily separable after the heat treatment.

The term “(meth)acrylic” herein means acrylic or methacrylic.

The (meth)acrylic copolymer preferably contains a structural unit derived from a branched alkyl (meth)acrylate. The presence of a structural unit derived from a branched alkyl (meth)acrylate improves the dispersibility of the (meth)acrylic copolymer in the resin composition. It also enhances surface localization of the (meth)acrylic copolymer, resulting in better separability of a temporary fixing material containing the resin composition.

The term “(meth)acrylate” herein means acrylate or methacrylate.

Examples of the branched alkyl (meth)acrylate include t-butyl (meth)acrylate, isobutyl (meth)acrylate, isoamyl (meth)acrylate, 2-ethylhexyl (meth)acrylate, isononyl (meth)acrylate, isodecyl (meth)acrylate, isostearyl (meth)acrylate, isooctyl (meth)acrylate, and isoundecyl (meth)acrylate.

The lower limit of the proportion of the structural unit derived from a branched alkyl (meth)acrylate in the (meth)acrylic copolymer is preferably 20 mol % and the upper limit thereof is preferably 80 mol %. When the proportion of the structural unit derived from a branched alkyl (meth)acrylate is 20 mol % or greater and 80 mol % or less, surface localization of the (meth)acrylic copolymer in the resin composition can be further enhanced. As a result, a temporary fixing material containing the resulting resin composition has better separability. The lower limit of the proportion of the structural unit derived from a branched alkyl (meth)acrylate is more preferably 30 mol % and the upper limit thereof is more preferably 70 mol %.

The (meth)acrylic copolymer may be one containing the structural unit derived from a branched alkyl (meth)acrylate and a structural unit derived from a linear alkyl (meth)acrylate.

Examples of the linear alkyl (meth)acrylate include methyl (meth)acrylate, ethyl (meth)acrylate, n-proopyl (meth)acrylate, n-butyl (meth)acrylate, n-pentyl (meth)acrylate, n-hexyl (meth)acrylate, n-heptyl (meth)acrylate, n-octyl (meth)acrylate, n-nonyl (meth)acrylate, lauryl (meth)acrylate, stearyl (meth)acrylate, n-decyl (meth)acrylate, and n-undecyl (meth)acrylate.

The (meth)acrylic copolymer preferably contains a structural unit derived from an alkyl (meth)acrylate containing an alkyl group with a carbon number of 2 or greater and 7 or less and a structural unit derived from an alkyl (meth)acrylate containing an alkyl group with a carbon number of 8 or greater. Containing a structural unit derived from an alkyl (meth)acrylate containing an alkyl group with a carbon number of 2 or greater and 7 or less and a structural unit derived from an alkyl (meth)acrylate containing an alkyl group with a carbon number of 8 or greater, the (meth)acrylic copolymer exhibits better dispersibility and better surface localization in the resulting resin composition.

The structural unit derived from a branched alkyl (meth)acrylate preferably has a carbon number of 8 or greater. When the structural unit derived from a branched alkyl (meth)acrylate has a carbon number of 8 or greater, surface localization of the (meth)acrylic copolymer in the resin composition can be further enhanced. As a result, a temporary fixing material containing the resulting resin composition has better separability. The structural unit derived from a branched alkyl (meth)acrylate preferably has a carbon number of 20 or less, preferably 15 or less, preferably 10 or less, particularly preferably 8.

The structural unit derived from a linear alkyl (meth)acrylate preferably has a carbon number of 2 or greater and 7 or less. When the structural unit derived from a linear alkyl (meth)acrylate has a carbon number of 2 or greater and 7 or less, surface localization of the (meth)acrylic copolymer in the resin composition can be further enhanced. As a result, a temporary fixing material containing the resulting resin composition has better separability. The structural unit derived from a linear alkyl (meth)acrylate more preferably has a carbon number of 3 or greater and 6 or less, particularly preferably 4.

Examples of the branched alkyl (meth)acrylate among the alkyl (meth)acrylates each containing an alkyl group with a carbon number of 2 or greater and 7 or less include t-butyl (meth)acrylate, isobutyl (meth)acrylate, and isoamyl (meth)acrylate.

Examples of the linear alkyl (meth)acrylate among the alkyl (meth)acrylates each containing an alkyl group with a carbon number of 2 or greater and 7 or less include methyl (meth)acrylate, ethyl (meth)acrylate, n-butyl (meth)acrylate, n-pentyl (meth)acrylate, n-hexyl (meth)acrylate, and n-heptyl (meth)acrylate. In order to enhance the surface localization of the (meth)acrylic copolymer in the resin composition of the present invention and improve the separability, preferred among these is n-butyl (meth)acrylate.

Examples of the branched alkyl (meth)acrylate among the alkyl (meth)acrylates each containing an alkyl group with a carbon number of 8 or greater include 2-ethylhexyl (meth)acrylate, isononyl (meth)acrylate, isodecyl (meth)acrylate, isostearyl (meth)acrylate, and isoundecyl (meth)acrylate.

Examples of the linear alkyl (meth)acrylate among the alkyl (meth)acrylates each containing an alkyl group with a carbon number of 8 or greater include n-octyl (meth)acrylate, n-nonyl (meth)acrylate, lauryl (meth)acrylate, stearyl (meth)acrylate, n-decyl (meth)acrylate, and n-undecyl (meth)acrylate.

In order to enhance the surface localization of the (meth)acrylic copolymer in the resin composition of the present invention and improve the separability, preferred among these is 2-ethylhexyl (meth)acrylate.

When the (meth)acrylic copolymer contains the structural unit derived from an alkyl (meth)acrylate containing an alkyl group with a carbon number of 2 or greater and 7 or less and the structural unit derived from an alkyl (meth)acrylate containing an alkyl group with a carbon number of 8 or greater, the lower limit of the proportion of the structural unit derived from an alkyl (meth)acrylate containing an alkyl group with a carbon number of 2 or greater and 7 or less in the (meth)acrylic copolymer is preferably 20 mol %, and the upper limit thereof is preferably 80 mol %. When the proportion of the structural unit derived from an alkyl (meth)acrylate containing an alkyl group with a carbon number of 2 or greater and 7 or less is 20 mol % or greater, the (meth)acrylic copolymer exhibits better dispersibility and better surface localization in the resulting resin composition. When the proportion of the structural unit derived from an alkyl (meth)acrylate containing an alkyl group with a carbon number of 2 or greater and 7 or less is 80 mol % or less, the resulting resin composition has better heat resistance. The lower limit of the proportion of the structural unit derived from an alkyl (meth)acrylate containing an alkyl group with a carbon number of 2 or greater and 7 or less is more preferably 30 mol % and the upper limit thereof is more preferably 70 mol %.

The (meth)acrylic copolymer preferably further contains a structural unit derived from a polar functional group-containing monomer. When the (meth)acrylic copolymer contains a structural unit derived from a polar functional group-containing monomer, the resulting resin composition has excellent heat resistance.

Examples of the structural unit derived from a polar functional group-containing monomer include a structural unit derived from a hydroxy group-containing monomer, a structural unit derived from a carboxy group-containing monomer, a structural unit derived from an epoxy group-containing monomer, a structural unit derived from an isocyanate group-containing monomer, and a structural unit derived from an amino group-containing monomer. To achieve still higher heat resistance, the (meth)acrylic copolymer preferably further contains a structural unit derived from a hydroxy group-containing monomer and/or a structural unit derived from an epoxy group-containing monomer.

Examples of the hydroxy group-containing monomer include 4-hydroxybutyl (meth)acrylate and 2-hydroxyethyl (meth)acrylate.

Examples of the carboxy group-containing monomer include acrylic acid and methacrylic acid.

Examples of the epoxy group-containing monomer include glycidyl (meth)acrylate.

Examples of the isocyanate group-containing monomer include 2-isocyanatoethyl (meth)acrylate.

Examples of the amino group-containing monomer include 2-aminoethyl (meth)acrylate.

The polar functional group-containing monomers may be used alone or in combination of two or more thereof.

The lower limit of the total proportion of the structural units derived from polar functional group-containing monomers contained in the (meth)acrylic copolymer is preferably 0.5 mol % and the upper limit thereof is preferably 30 mol %. When the total proportion of the structural units derived from polar functional group-containing monomers is 0.5 mol % or greater, the resulting resin composition has excellent heat resistance. When the total proportion of the structural units derived from polar functional group-containing monomers is 30 mol % or less, the resulting resin composition has excellent separability after heating. The lower limit of the total proportion of the structural units derived from polar functional group-containing monomers is more preferably 1 molo and the upper limit thereof is more preferably 20 mol %. The lower limit is still more preferably 5 mol % and the upper limit is still more preferably 15 mol %.

From the standpoint of facilitating surface localization of the (meth)acrylic copolymer in the resin composition and improving the separability of the resulting temporary fixing material, the (meth)acrylic copolymer preferably contains no carbon-carbon double bond-containing reactive functional group.

The lower limit of the molecular weight of the (meth)acrylic copolymer is preferably 2,000 and the upper limit thereof is preferably 50,000. When the (meth)acrylic copolymer has a molecular weight of 2,000 or greater, the resulting resin composition has better heat resistance. When the (meth)acrylic copolymer has a molecular weight of 50,000 or less, the (meth)acrylic copolymer has better dispersibility and better surface localization in the resulting resin composition. As a result, a temporary fixing material containing the resulting resin composition has better separability. The lower limit of the molecular weight of the (meth)acrylic copolymer is more preferably 5,000, still more preferably 6,000 and the upper limit thereof is more preferably 20,000, still more preferably 15,000, further preferably 10,000.

The term “molecular weight” herein refers to the molecular weight determined from the structural formula for compounds whose molecular structure is specified, but for compounds with a wide distribution of polymerization degrees and compounds whose modification site is unspecified, it refers to the weight average molecular weight. The weight average molecular weight is measured by gel permeation chromatography (GPC) as a polystyrene equivalent molecular weight. Specifically, it can be measured using an Acquity APC system (produced by Waters Corporation) under the conditions of a mobile phase of THE, a flow rate of 1.0 mL/min, a column temperature of 40 °C, a sample concentration of 0.2 molo, and an RI/PDA detector. The column used may be HR-MB-M (produced by Waters Corporation, 6.0×150 mm).

The lower limit of the glass transition temperature of the (meth)acrylic copolymer is preferably −70 °C and the upper limit thereof is preferably −5 °C. With the glass transition temperature within this range, the (meth)acrylic copolymer has better dispersibility and better surface localization in the resulting resin composition. As a result, a temporary fixing material containing the resulting resin composition has better separability. The lower limit of the glass transition temperature of the (meth)acrylic copolymer is more preferably −65 °C, still more preferably −60 °C and the upper limit thereof is more preferably −10 °C, still more preferably −20 °C, even more preferably −30 °C.

The term “glass transition temperature” herein refers to a temperature at which a maximum resulting from a micro-Brownian motion, among maxima of a loss tangent (tan δ) obtained in measuring dynamic viscoelasticity, appears. The glass transition temperature can be measured by a known method using a dynamic mechanical analyzer. The glass transition temperature (absolute temperature) of the (meth)acrylic copolymer can be also determined by dividing the proportion by the glass transition temperature for each monomer component constituting the (meth)acrylic copolymer ((proportion of monomer component (mol %))/(glass transition temperature (K) of monomer component)) and calculating the reciprocal of the sum of the obtained values of all monomer components constituting the (meth)acrylic copolymer.

The lower limit of the hydroxy value of the (meth)acrylic copolymer is preferably 1 mgKOH/g and the upper limit thereof is preferably 100 mgKOH/g. When the (meth)acrylic copolymer has a hydroxy value of 1 mgKOH/g or greater, the resulting resin composition has excellent heat resistance. When the (meth)acrylic copolymer has a hydroxy value of 100 mgKOH/g or less, the resulting resin composition has excellent separability after heating. The lower limit of the hydroxy value of the (meth)acrylic copolymer is more preferably 5 mgKOH/g and the upper limit thereof is more preferably 50 mgKOH/g. The lower limit is still more preferably 10 mgKOH/g and the upper limit is still more preferably 30 mgKOH/g.

The hydroxy value of the (meth)acrylic copolymer can be measured by, for example, potentiometric titration in conformity with JIS K 0070:1992.

The lower limit of the amount of the (meth)acrylic copolymer is preferably 0.1 parts by mass and the upper limit thereof is preferably 20 parts by mass, relative to 100 parts by mass of a later-described resin having an imide skeleton in a backbone repeating unit (in the case where the resin composition contains a later-described polyfunctional monomer or oligomer, 100 parts by mass of a total of the resin having an imide skeleton in a backbone repeating unit and the polyfunctional monomer or oligomer). When the amount of the (meth)acrylic copolymer is within this range, a temporary fixing material produced using the resulting resin composition reduces contamination of the adherend and has better separability. The lower limit of the amount of the (meth)acrylic copolymer is more preferably 0.2 parts by mass and the upper limit thereof is more preferably 15 parts by mass.

The resin composition of the present invention contains a resin having an imide skeleton in a backbone repeating unit.

The resin having an imide skeleton in a backbone repeating unit has remarkably excellent heat resistance because of the presence of the imide skeleton, and is less likely to suffer degradation of the backbone even in heat treatment at high temperature. Therefore, a temporary fixing material produced using the resulting resin composition containing the resin having an imide skeleton in a backbone repeating unit can reduce the occurrence of voids and partial detachment between the temporary fixing material and the support during heat treatment at high temperature, and also can prevent a rise in adhesion to the adherend or the generation of adhesive deposits upon separation from the adherend.

The resin having an imide skeleton in a backbone repeating unit preferably contains a structural unit represented by the formula (1).

In the formula (1), P¹ is preferably an aromatic group with a carbon number of 5 or greater and 50 or less. When P¹ is an aromatic group with a carbon number of 5 or greater and 50 or less, the resulting resin composition has better heat resistance. In other words, the temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend.

In the formula (1), Q¹ is preferably a substituted or unsubstituted linear, branched, or cyclic aliphatic group with a carbon number of 2 or greater and 100 or less. When Q¹ is a substituted or unsubstituted linear, branched, or cyclic aliphatic group with a carbon number of 2 or greater and 100 or less, a temporary fixing material produced using the resulting resin composition has better light transmission. Also, a temporary fixing material produced using the resulting resin composition can have better flexibility, and thus can exhibit high conformability to adherends with irregularities and can be more easily separated upon separation.

Q¹ is also preferably an aliphatic group derived from a diamine compound. In particular, Q¹ is preferably an aliphatic group derived from a dimer diamine from the standpoint of the light transmission, the flexibility, and the compatibility of the resin having an imide skeleton in a backbone repeating unit with solvents and other components.

The dimer diamine is a diamine compound obtainable by reducing and aminating cyclic or acyclic dimer acid obtained as a dimer of an unsaturated fatty acid, and examples thereof include linear, monocyclic, and polycyclic dimer diamines. The dimer diamine may contain a carbon-carbon double bond and may be a hydrogenated product obtained by adding hydrogen.

The aliphatic group derived from a dimer diamine is preferably, for example, at least one selected from the group consisting of a group represented by the following formula (2-1), a group represented by the following formula (2-2), a group represented by the following formula (2-3), and a group represented by the following formula (2-4). More preferred among these is a group represented by the following formula (2-2).

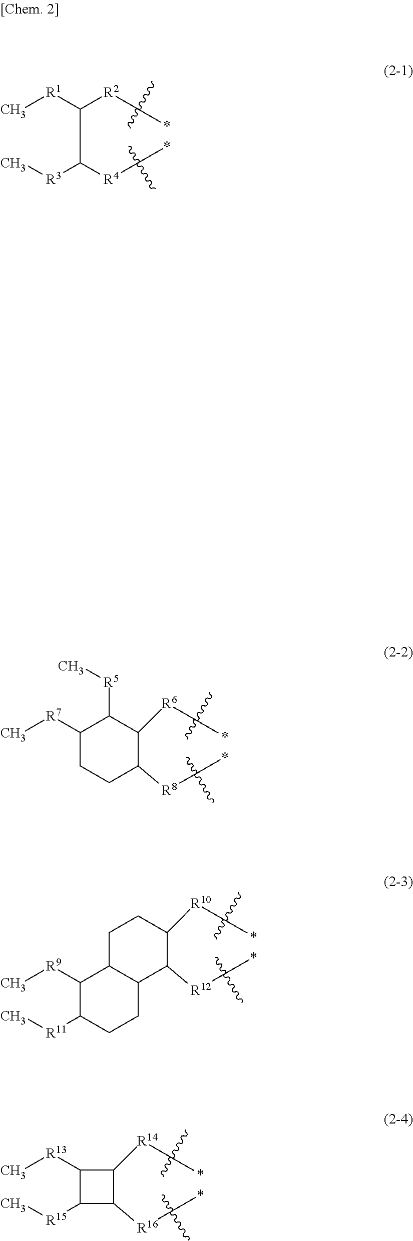

In the formulas (2-1) to (2-4), R¹ to R¹⁶ each independently represent a linear or branched hydrocarbon group and * represents a bond. A bond “*” binds to N in the formula (1).

In the formulas (2-1) to (2-4), the hydrocarbon groups represented by R¹ to R¹⁶ may be saturated hydrocarbon groups or unsaturated hydrocarbon groups. A combination of R¹ and R², a combination of R³ and R⁴, a combination of R⁵ and R⁶, a combination of R⁷ and R⁸, a combination of R⁹ and R¹⁰, a combination of R¹¹ and R¹², a combination of R¹³ and R¹⁴, and a combination of R¹⁵ and R¹⁶ each preferably has a total carbon number of 7 or greater and 50 or less. When the total carbon number is within the above range, the resulting resin composition can have better light transmission and better flexibility, and the resin having an imide skeleton in a backbone repeating unit can have better compatibility with solvents and other components. The total carbon number is more preferably 9 or greater, still more preferably 12 or greater, even more preferably 14 or greater. The total carbon number is more preferably 35 or less, still more preferably 25 or less, even more preferably 18 or less.

No limitation is given on the optical isomerism of the group represented by the formula (2-1), the group represented by the formula (2-2), the group represented by the formula (2-3), and the group represented by the formula (2-4), and any optical isomers may be included.

The resin having an imide skeleton in a backbone repeating unit preferably contains a resin containing no maleimide group and having an imide skeleton in a backbone repeating unit, more preferably contains a resin containing no carbon-carbon double bond-containing reactive functional group and having an imide skeleton in a backbone repeating unit.

The resin containing no maleimide group and having an imide skeleton in a backbone repeating unit preferably has a weight average molecular weight of 10,000 or greater and 2,000,000 or less. When the resin containing no maleimide group and having an imide skeleton in a backbone repeating unit has a weight average molecular weight of 10,000 or greater, the resulting resin composition has better heat resistance. In other words, a temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend. When the resin containing no maleimide group and having an imide skeleton in a backbone repeating unit has a weight average molecular weight of 2,000,000 or less, the resin containing no maleimide group and having an imide skeleton in a backbone repeating unit has better compatibility with solvents and other components. The lower limit of the weight average molecular weight of the resin containing no maleimide group and having an imide skeleton in a backbone repeating unit is more preferably 30,000 and the upper limit thereof is more preferably 1,000,000. The lower limit is still more preferably 40,000 and the upper limit is still more preferably 300,000. The lower limit is even more preferably 50,000.

Specifically, the resin containing no maleimide group and having an imide skeleton in a backbone repeating unit is, for example, a resin containing a structural unit represented by the formula (1) and having functional groups containing no maleimide group at both ends.

The resin containing a structural unit represented by the formula (1) and having functional groups containing no maleimide group at both ends may contain a structural unit represented by the following formula (3):

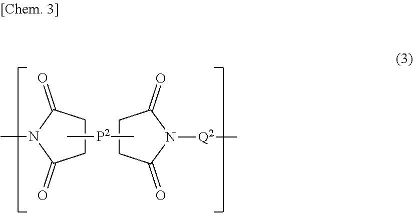

wherein P² represents an aromatic group and 02 represents a substituted or unsubstituted aromatic structure-containing group.

In the formula (3), P² is preferably an aromatic group with a carbon number of 5 or greater and 50 or less. When P² is an aromatic group with a carbon number of 5 or greater and 50 or less, the resulting resin composition has better heat resistance. In other words, a temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend.

In the formula (3), Q² is preferably a substituted or unsubstituted C5-C50 aromatic structure-containing group. When Q² is a substituted or unsubstituted C5-C50 aromatic structure-containing group, the resulting resin composition has better heat resistance. In other words, a temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend.

Examples of the functional group containing no maleimide group include aliphatic groups, alicyclic groups, aromatic groups, acid anhydride groups, and amino groups. Specific examples include an unreacted one-end group of an acid anhydride that is a raw material of the resin containing no maleimide group and having an imide skeleton in a backbone repeating unit and an unreacted one-end group of a diamine compound that is a raw material of the resin.

In the resin containing a structural unit represented by the formula (1) and having functional groups containing no maleimide group at both ends, the functional groups containing no maleimide group at both ends may be the same as or different from each other.

The proportion of the structural unit represented by the formula (1) in the resin containing a structural unit represented by the formula (1) and having functional groups containing no maleimide group at both ends is preferably 30 molo or greater, more preferably 50 mol % or greater, while preferably 90 mol % or less, more preferably 80 mol % or less.

When the resin containing a structural unit represented by the formula (1) and having functional groups containing no carbon-carbon double bond at both ends contains a structural unit represented by the formula (3), the proportion of the structural unit represented by the formula (3) is preferably 5 mol % or greater, more preferably 10 mol % or greater, still more preferably 20 molo or greater, while preferably 50 mol % or less, more preferably 30 mol % or less.

When the proportions of the structural unit represented by the formula (1) and the structural unit represented by the formula (3) are within the ranges, a temporary fixing material produced using the resulting resin composition can further reduce the occurrence of voids and partial detachment between the temporary fixing material and the support during heat treatment at high temperature and can be more easily separated upon separation from the adherend.

The structural unit represented by the formula (1) and the structural unit represented by the formula (3) may have a block structure including block components in which the structural units are each arranged in series or a random structure in which the structural units are randomly arranged.

The resin containing no maleimide group and having an imide skeleton in a backbone repeating unit can be produced, for example, by a method including reacting a diamine compound with an aromatic acid anhydride.

The diamine compound used may be an aliphatic diamine compound or an aromatic diamine compound.

Using an aliphatic diamine compound as the diamine compound further improves the light transmission of the resulting resin composition. Also, the resulting resin composition can have better flexibility, and thus a temporary fixing material produced using the resulting resin composition can exhibit high conformability to adherends with irregularities and can be more easily separated upon separation.

Using an aromatic diamine compound as the diamine compound further improves the heat resistance of the resulting resin composition.

The diamine compounds may be used alone or in combination of two or more thereof.

Examples of the aliphatic diamine compound include 1,10-diaminodecane, 1,12-diaminododecane, dimer diamine, 1,2-diamino-2-methylpropane, 1,2-diaminocyclohexane, 1,2-diaminopropane, 1,3-diaminopropane, 1,4-diaminobutane, 1,5-diaminopentane, 1,7-diaminoheptane, 1,8-diaminomentane, 1,8-diaminooctane, 1,9-diaminononane, 3,3′-diamino-N-methyldipropylamine, diaminomaleonitrile, 1,3-diaminopentane, bis(4-amino-3-methylcyclohexyl) methane, 1,2-bis(2-aminoethoxy) ethane, and 3 (4), 8 (9)-bis(aminomethyl) tricyclo (5.2.1.02,6) decane.

Among the aliphatic diamine compounds, preferred is a dimer diamine from the standpoint of the light transmission, the flexibility, and the compatibility of the resin containing no maleimide group and having an imide skeleton in a backbone repeating unit with solvents and other components. In other words, the resin containing no maleimide group and having an imide skeleton in a backbone repeating unit preferably has an aliphatic group derived from a dimer diamine.

Examples of the dimer diamine include a dimer diamine capable of constituting at least one group selected from the group consisting of a group represented by the formula (2-1), a group represented by the formula (2-2), a group represented by the formula (2-3), and a group represented by the formula (2-4).

Examples of the aromatic diamine compound include 9,10-diaminophenanthrene, 4,4′-diaminooctafluorobiphenyl, 3,7-diamino-2-methoxyfluorene, 4,4′-diaminobenzophenone, 3,4-diaminobenzophenone, 3,4-diaminotoluene, 2,6-diaminoanthraquinone, 2,6-diaminotoluene, 2,3-diaminotoluene, 1,8-diaminonaphthalene, 2,4-diaminotoluene, 2,5-diaminotoluene, 1,4-diaminoanthraquinone, 1,5-diaminoanthraquinone, 1,5-diaminonaphthalene, 1,2-diaminoanthraquinone, 2,4-cumenediamine, 1,3-bisaminomethylbenzene, 1,3-bisaminomethylcyclohexane, 2-chloro-1,4-diaminobenzene, 1,4-diamino-2,5-dichlorobenzene, 1,4-diamino-2,5-dimethylbenzene, 4,4′-diamino-2,2′-bistrifluoromethylbiphenyl, bis(amino-3-chlorophenyl) ethane, bis(4-amino-3,5-dimethylphenyl) methane, bis(4-amino-3,5-diethylphenyl) methane, bis(4-amino-3-ethyldiamino) fluorene, 2,3-diaminonaphthalene, 2,3-diaminophenol,-5-methylphenyl) methane, bis(4-amino-3-methylphenyl) methane, bis(4-amino-3-ethylphenyl) methane, 4,4′-diaminophenylsulfone, 3,3′-diaminophenylsulfone, 2,2-bis(4, (4-aminophenoxy)phenyl) sulfone, 2,2-bis(4-(3-aminophenoxy)phenyl) sulfone, 4,4′-oxydianiline, 4,4′-diaminodiphenylsulfide, 3,4′-oxydianiline, 2,2-bis(4-(4-aminophenoxy)phenyl) propane, 1,3-bis(4-aminophenoxy)benzene, 4,4′-bis(4-aminophenoxy) biphenyl, 4,4′-diamino-3,3′-dihydroxybiphenyl, 4,4′-diamino-3,3′-dimethylbiphenyl, 4,4′-diamino-3,3′-dimethoxybiphenyl, Bisaniline M, Bisaniline P, 9,9-bis(4-aminophenyl) fluorene, o-tolidine sulfone, methylene bis(anthranilic acid), 1,3-bis(4-aminophenoxy)-2,2-dimethylpropane, 1,3-bis(4-aminophenoxy) propane, 1,4-bis(4-aminophenoxy) butane, 1,5-bis(4-aminophenoxy) butane, 2,3,5,6-tetramethyl-1,4-phenylene diamine, 3,3′,5,5′-tetramethylbenzidine, 4,4′-diaminobenzanilide, 2,2-bis(4-aminophenyl) hexafluoropropane, polyoxyalkylene diamines (e.g., Jeffamine D-230, D400, D-2000, and D-4000 produced by Huntsman), 1,3-cyclohexane bis(methylamine), m-xylylenediamine, and p-xylylenediamine.

Examples of the aromatic acid anhydride include acid anhydrides of carboxylic acids such as pyromellitic acid, 1,2,5,6-naphthalenetetracarboxylic acid, 2,3,6,7-naphthalenetetracarboxylic acid, 1,2,4,5-naphthalenetetracarboxylic acid, 1,4,5,8-naphthalenetetracarboxylic acid, 3,3′,4,4′-benzophenonetetracarboxylic acid, 3,3′,4,4′-biphenylethertetracarboxylic acid, 3,3′,4,4′-biphenyltetracarboxylic acid, 2,3,5,6-pyridinetetracarboxylic acid, 3,4,9,10-perylenetetracarboxylic acid, 4,4′-sulfonyldiphthalic acid, 1-trifluoromethyl-2,3,5,6-benzenetetracarboxylic acid, 2,2′,3,3′-biphenyltetracarboxylic acid, 2,2-bis(3,4-dicarboxyphenyl) propane, 2,2-bis(2,3-dicarboxyphenyl) propane, 1,1-bis(2,3-dicarboxyphenyl) ethane, 1,1-bis(3,4-dicarboxyphenyl) ethane, bis(2,3-dicarboxyphenyl) methane, bis(3,4-dicarboxyphenyl) methane, bis(3,4-dicarboxyphenyl) sulfone, bis(3,4-dicarboxyphenyl) ether, benzene-1,2,3,4-tetracarboxylic acid, 2,3,2′,3′-benzophenonetetracarboxylic acid, 2,3,3′,4′-benzophenonetetracarboxylic acid, phenanthrene-1,8,9,10-tetracarboxylic acid, pyrazine-2,3,5,6-tetracarboxylic acid, thiophene-2, 3, 4,5-tetracarboxylic acid, 2,3,3′,4′-biphenyltetracarboxylic acid, 3,4,3′,4′-biphenyltetracarboxylic acid, 2,3,2′,3′-biphenyltetracarboxylic acid, 4,4′-bis(3,4-dicarboxyphenoxy)diphenyl sulfide, and 4,4′-(4,4′-isopropylidenediphenoxy)-bis(phthalic acid).

The lower limit of the amount of the resin containing no maleimide group and having an imide skeleton in a backbone repeating unit is 10 parts by mass and the upper limit thereof is preferably 90 parts by mass, in 100 parts by mass of the resin having an imide skeleton in a backbone repeating unit. When the amount of the resin containing no maleimide group and having an imide skeleton in a backbone repeating unit is within this range, a temporary fixing material produced using the resulting resin composition can be more easily separated upon separation from the adherend. To further increase the separability, the lower limit of the amount of the resin containing no maleimide group and having an imide skeleton in a backbone repeating unit is more preferably 20 parts by mass, and the upper limit thereof is more preferably 80 parts by mass.

The resin composition of the present invention may be thermosetting or photocurable. Alternatively, it may be non-curable.

When the resin composition of the present invention is thermosetting or photocurable, the resin having an imide skeleton in a backbone repeating unit preferably contains a resin containing a carbon-carbon double bond-containing reactive functional group and having an imide skeleton in a backbone repeating unit. When the resin having an imide skeleton in a backbone repeating unit contains the resin containing a carbon-carbon double bond-containing reactive functional group and having an imide skeleton in a backbone repeating unit, the resulting resin composition as a whole can uniformly and quickly polymerize and crosslink when heated or irradiated with light. The resulting increase in the modulus of elasticity greatly decreases adhesion. This can prevent a temporary fixing material produced using the resulting resin composition from suffering a rise in adhesion to the adherend or the generation of adhesive deposits upon separation from the adherend.

When the resin having an imide skeleton in a backbone repeating unit contains the resin containing no maleimide group and having an imide skeleton in a backbone repeating unit, the resin having an imide skeleton in a backbone repeating unit may further contain a resin containing a carbon-carbon double bond-containing reactive functional group and having an imide skeleton in a backbone repeating unit, in addition to the resin containing no maleimide group and having an imide skeleton in a backbone repeating unit.

Examples of the carbon-carbon double bond-containing reactive functional group include an optionally substituted maleimide group, an optionally substituted citraconimide group, an optionally substituted vinyl ether group, an optionally substituted allyl group, and an optionally substituted (meth)acryloyl group. For higher heat resistance, preferred among these is an optionally substituted maleimide group.

The term “(meth)acryloyl” herein means acryloyl or methacryloyl.

The resin containing a carbon-carbon double bond-containing reactive functional group and having an imide skeleton in a backbone repeating unit preferably has a carbon-carbon double bond-containing reactive functional group equivalent (weight average molecular weight/number of carbon-carbon double bond-containing reactive functional groups) of 4,000 or less. When the carbon-carbon double bond-containing reactive functional group equivalent is 4,000 or less, the resulting resin composition has better heat resistance. A resin containing carbon-carbon double bond-containing reactive functional groups at a density not lower than a certain level in the molecule has a shorter distance between crosslinking points, which presumably further reduces a rise in adhesion. The carbon-carbon double bond-containing reactive functional group equivalent is more preferably 3,000 or less, still more preferably 2,000 or less.

The lower limit of the carbon-carbon double bond-containing reactive functional group equivalent is not limited but is practically about 600.

The resin containing a carbon-carbon double bond-containing reactive functional group and having an imide skeleton in a backbone repeating unit preferably has a weight average molecular weight of 1,000 or greater and 100,000 or less. When the weight average molecular weight of the resin containing a carbon-carbon double bond-containing reactive functional group and having an imide skeleton in a backbone repeating unit is 1,000 or greater, the resulting resin composition can easily form a film, and a temporary fixing material produced using the resulting resin composition exhibits flexibility to some degree. Such a temporary fixing material can exhibit high conformability to adherends with irregularities and can be more easily separated upon separation. When the weight average molecular weight of the resin containing a carbon-carbon double bond-containing reactive functional group and having an imide skeleton in a backbone repeating unit is 100,000 or less, an excessive decrease in solubility of the resin containing a carbon-carbon double bond-containing reactive functional group and having an imide skeleton in a backbone repeating unit in solvents can be prevented. The resin containing a carbon-carbon double bond-containing reactive functional group and having an imide skeleton in a backbone repeating unit more preferably has a weight average molecular weight of 1,500 or greater and 50,000 or less, still more preferably 2,000 or greater and 20,000 or less.

In the resin containing a carbon-carbon double bond-containing reactive functional group and having an imide skeleton in a backbone repeating unit, the carbon-carbon double bond-containing reactive functional group may be present either in a side chain or at an end. The carbon-carbon double bond-containing reactive functional groups are preferably present at both ends, more preferably present also in a side chain in addition to at both ends.

The carbon-carbon double bond-containing reactive functional groups at both ends in the resin containing a carbon-carbon double bond-containing reactive functional group and having an imide skeleton in a backbone repeating unit have high reactivity and thus allow the resin composition to more sufficiently cure, for example, when irradiated with light. As a result, a rise in adhesion or the generation of adhesive deposits upon separation can be further prevented.

Moreover, the presence of the carbon-carbon double bond-containing reactive functional group in a side chain in the resin containing a carbon-carbon double bond-containing reactive functional group and having an imide skeleton in a backbone repeating unit allows the resulting resin composition to have better heat resistance. This is presumably because a shorter distance between crosslinking points can further reduce a rise in adhesion. Also, the presence of the carbon-carbon double bond-containing reactive functional group in a side chain in the resin containing a carbon-carbon double bond-containing reactive functional group and having an imide skeleton in a backbone repeating unit facilitates adjustment of the functional group equivalent to 4,000 or less while setting the weight average molecular weight to 1,000 or greater. This allows the resulting resin composition to exhibit sufficient initial adhesion and further prevents a rise in adhesion or the generation of adhesive deposits upon separation.

As described above, the carbon-carbon double bond-containing reactive functional group in the resin containing a carbon-carbon double bond-containing reactive functional group and having an imide skeleton in a backbone repeating unit may be present either in a side chain or at an end. When a functional group other than the carbon-carbon double bond-containing reactive functional group (functional group containing no carbon-carbon double bond) is present either in a side chain or at an end, examples of the functional group containing no carbon-carbon double bond include aliphatic groups, alicyclic groups, aromatic groups, acid anhydride groups, and amino groups. Specific examples include an unreacted one-end group of an acid anhydride that is a raw material of the resin containing a carbon-carbon double bond-containing reactive functional group and having an imide skeleton in a backbone repeating unit and an unreacted one-end group of a diamine compound that is a raw material of the resin. When the resin containing a carbon-carbon double bond-containing reactive functional group and having an imide skeleton in a backbone repeating unit has two or more functional groups containing no carbon-carbon double bond in side chains or at ends, the functional groups containing no carbon-carbon double bond may be the same as or different from each other.

Specifically, the resin containing a carbon-carbon double bond-containing reactive functional group and having an imide skeleton in a backbone repeating unit is, for example, a resin containing a structural unit represented by the formula (1) and having a carbon-carbon double bond-containing reactive functional group at least either at an end or in a side chain.

The resin containing a structural unit represented by the formula (1) and having a carbon-carbon double bond-containing reactive functional group at least either at an end or in a side chain may contain at least one structural unit selected from the group consisting of a structural unit represented by the following formula (4-1) and a structural unit represented by the following formula (4-2).

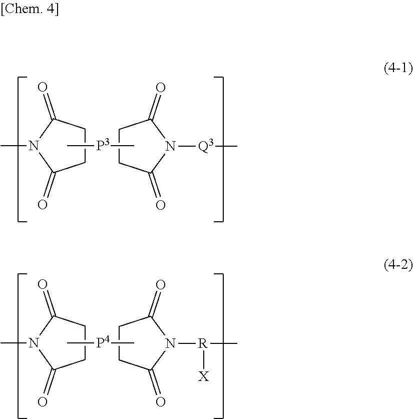

In the formula (4-1), P³ represents an aromatic group and Q³ represents a substituted or unsubstituted aromatic structure-containing group. In the formula (4-2), P⁴ represents an aromatic group, R represents a substituted or unsubstituted branched aliphatic or aromatic group, and X represents a carbon-carbon double bond-containing reactive functional group.

P³ in the formula (4-1) and P⁴ in the formula (4-2) are preferably C5-C50 aromatic groups. When P³ and P⁴ are C5-C50 aromatic groups, the resulting resin composition has better heat resistance. In other words, a temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend.

In the formula (4-1), Q³ is preferably a substituted or unsubstituted C5-C50 aromatic structure-containing group. When Q³ is a substituted or unsubstituted C5-C50 aromatic structure-containing group, the resulting resin composition has better heat resistance. In other words, a temporary fixing material produced using the resulting resin composition can further reduce the occurrence of voids and partial detachment between the temporary fixing material and the support during heat treatment at high temperature, and also can further prevent a rise in adhesion to the adherend or the generation of adhesive deposits upon separation from the adherend.

In the formula (4-2), R is preferably a substituted or unsubstituted branched C2-C100 aliphatic group or aromatic group. When R is a substituted or unsubstituted branched C2-C100 aliphatic group or aromatic group, the resulting resin composition has better flexibility, and thus a temporary fixing material produced using the resin composition can exhibit high conformability to adherends with irregularities and can be more easily separated upon separation.

In the formula (4-2), preferably, R is an aromatic ester group- or aromatic ether group-containing aromatic group, and the aromatic ester group or the aromatic ether group in R binds to X.

Here, the “aromatic ester group” refers to a group in which an ester group directly binds to an aromatic ring and the “aromatic ether group” refers to a group in which an ether group directly binds to an aromatic ring. When an aromatic group thus serves as a site binding to an ester group or ether group, the resulting resin composition has better heat resistance. In other words, a temporary fixing material produced using the resulting resin composition can further reduce the occurrence of voids and partial detachment during heat treatment at high temperature, and also can further prevent a rise in adhesion to the adherend or the generation of adhesive deposits upon separation from the adherend. As X binds to R via an aromatic ester group or aromatic ether group, the carbon-carbon double bond in X does not conjugate with R, so that polymerization and crosslinking under heating or irradiation with light are not disturbed.

The proportion of the structural unit represented by the formula (1) in the resin containing a structural unit represented by the formula (1) and having a carbon-carbon double bond-containing reactive functional group at least either at an end or in a side chain is preferably 30 mol % or greater, more preferably 50 mol % or greater, while preferably 90 mol % or less, more preferably 80 mol % or less.

When the resin containing a structural unit represented by the formula (1) and having a carbon-carbon double bond-containing reactive functional group at least either at an end or in a side chain contains a structural unit represented by the formula (4-1), the proportion of the structural unit represented by the formula (4-1) is preferably 5 mol % or greater, more preferably 10 mol % or greater, still more preferably 20 mol % or greater, while preferably 50 mol % or less, more preferably 30 mol % or less.

When the resin containing a structural unit represented by the formula (1) and having a carbon-carbon double bond-containing reactive functional group at least either at an end or in a side chain contains a structural unit represented by the formula (4-2), the proportion of the structural unit represented by the formula (4-2) is preferably 10 mol % or greater, more preferably 20 mol % or greater, while preferably 50 mol % or less, more preferably 30 mol % or less.

When the proportions of the structural units represented by the formulas (1), (4-1), and (4-2) are within the ranges, a temporary fixing material produced using the resulting resin composition can further reduce the occurrence of voids and partial detachment between the temporary fixing material and the support during heat treatment at high temperature and can be more easily separated upon separation from the adherend.

The structural unit represented by the formula (1), the structural unit represented by the formula (4-1), and the structural unit represented by the formula (4-2) may each have a block structure including block components in which the structural units are each arranged in series or a random structure in which the structural units are randomly arranged.

The resin containing a carbon-carbon double bond-containing reactive functional group and having an imide skeleton in a backbone repeating unit can be produced, for example, by the following method.

Specifically, a diamine compound and an aromatic acid anhydride are first reacted to prepare an imide compound. Next, the functional group of the imide compound is reacted with a compound containing a functional group reactive with the functional group and a carbon-carbon double bond-containing reactive functional group (hereafter, also referred to as “functional group-containing unsaturated compound), thereby obtaining the resin containing a carbon-carbon double bond-containing reactive functional group and having an imide skeleton in a backbone repeating unit.

Alternatively, the resin containing a carbon-carbon double bond-containing reactive functional group and having an imide skeleton in a backbone repeating unit can also be obtained by reacting a diamine compound with an aromatic acid anhydride to prepare an imide compound and further reacting, for example, maleic anhydride with an end of the imide compound.

The diamine compound and aromatic acid anhydride used in the production method of the resin containing a carbon-carbon double bond-containing reactive functional group and having an imide skeleton in a backbone repeating unit may be those used in the production method of the resin containing no maleimide group and having an imide skeleton in a backbone repeating unit.

The functional group-containing unsaturated compound to be used is selected in accordance with the functional group at an end or in a side chain of the imide compound. For example, when the functional group at an end or in a side chain of the imide compound is a hydroxy group, examples of the functional group-containing unsaturated compound include a carboxy group-containing maleimide compound, an ether group-containing vinyl compound, a glycidyl group-containing allyl compound, a glycidyl group-containing allyl ether compound, a glycidyl group-containing vinyl ether compound, an isocyanate group-containing allyl compound, and an isocyanate group-containing (meth)acrylloyl compound.

For example, when the functional group at an end or in a side chain of the imide compound is a carboxy group, examples of the functional group-containing unsaturated compound include a hydroxy group-containing allyl compound, a glycidyl group-containing allyl compound, a glycidyl group-containing allyl ether compound, and a glycidyl group-containing vinyl ether compound.

Examples of the carboxy group-containing maleimide compound include maleimidoacetic acid, maleimidopropionic acid, maleimidobutyric acid, maleimidohexanoic acid, trans-4-(N-maleimidomethyl)cyclohexane-1-carboxylic acid, and 19-maleimido-17-oxo-4,7,10,13-tetraoxa-16-azanonadecanoic acid.

Examples of the ether group-containing vinyl compound include butyl vinyl ether.

Examples of the glycidyl group-containing allyl compound include diallyl monoglycidyl isocyanurate.

Examples of the glycidyl group-containing allyl ether compound include allyl glycidyl ether, glycerol diallyl monoglycidyl ether.

Examples of the glycidyl group-containing vinyl ether compound include glycidyl oxyethyl vinyl ether, glycidyl oxybutyl vinyl ether, glycidyl oxyhexyl vinyl ether, glycidyl diethylene glycol vinyl ether, and glycidyl cyclohexane dimethanol monovinyl ether.

Examples of the isocyanate group-containing allyl compound include allyl isocyanate.

Examples of the isocyanate group-containing (meth)acryloyl compound include 2-(meth)acryloyl oxyethyl isocyanate.

Examples of the hydroxy group-containing allyl compound include trimethylol propane diallyl ether and pentaerythritol triallyl ether.

The lower limit of the amount of the resin containing a carbon-carbon double bond-containing reactive functional group and having an imide skeleton in a backbone repeating unit is preferably 10 parts by mass and the upper limit thereof is preferably 100 parts by mass, in 100 parts by mass of the resin having an imide skeleton in a backbone repeating unit. When the amount of the resin containing a carbon-carbon double bond-containing reactive functional group and having an imide skeleton in a backbone repeating unit is within this range, a temporary fixing material produced using the resulting resin composition can be more easily separated upon separation. To further increase the separability, the lower limit of the amount of the resin containing a carbon-carbon double bond-containing reactive functional group and having an imide skeleton in a backbone repeating unit is more preferably 20 parts by mass, still more preferably 30 parts by mass and the upper limit thereof is more preferably 90 parts by mass, still more preferably 80 parts by mass, even more preferably 70 parts by mass.

When the resin having an imide skeleton in a backbone repeating unit contains the resin containing no maleimide group and having an imide skeleton in a backbone repeating unit, the resin composition of the present invention preferably further contains a polyfunctional monomer or oligomer containing two or more carbon-carbon double bond-containing reactive functional groups in a molecule and having a molecular weight of 5,000 or less (hereafter, also simply referred to as “polyfunctional monomer or oligomer”).

Also, when the resin having an imide skeleton in a backbone repeating unit contains the resin containing a carbon-carbon double bond-containing reactive functional group and having an imide skeleton in a backbone repeating unit, the resin composition of the present invention may further contain the polyfunctional monomer or oligomer.

The presence of the polyfunctional monomer or oligomer allows more efficient formation of a three-dimensional network of the resulting resin composition by, for example, irradiation with light, and a rise in adhesion or the generation of adhesive deposits upon separation can be further prevented.

The weight average molecular weight of the polyfunctional monomer or oligomer is more preferably less than 5,000.

When the resin having an imide skeleton in a backbone repeating unit itself is not reactive, the resin composition of the present invention can be reactive as a whole when further containing a different component containing a reactive functional group. The polyfunctional monomer or oligomer is preferably used as such a different component containing a reactive functional group. The case where the resin having an imide skeleton in a backbone repeating unit itself is not reactive may be, for example, a case where the resin having an imide skeleton in a backbone repeating unit consists of the resin containing no maleimide group and having an imide skeleton in a backbone repeating unit.

Examples of the carbon-carbon double bond-containing reactive functional group in the polyfunctional monomer or oligomer include an optionally substituted maleimide group, an optionally substituted citraconimide group, an optionally substituted vinyl ether group, an optionally substituted allyl group, and an optionally substituted (meth)acryloyl group. For higher heat resistance, an optionally substituted maleimide group is favorable among these. The polyfunctional monomer or oligomer is preferably a bismaleimide compound.

The polyfunctional monomer or oligomer preferably contains a group derived from a diamine compound. The diamine compound may be an aliphatic diamine compound or an aromatic diamine compound but is preferably an aliphatic diamine compound. In other words, the polyfunctional monomer or oligomer more preferably contains an aliphatic group derived from a diamine compound. Using an aliphatic diamine compound as the diamine compound further improves the light transmission of the resulting resin composition. Also, the resulting resin composition has better flexibility, and thus a temporary fixing material produced using the resulting resin composition can exhibit high conformability to adherends with irregularities and can be more easily separated upon separation.

Among the aliphatic diamine compounds, preferred is a dimer diamine described above from the standpoint of the light transmission, the flexibility, and the compatibility of the polyfunctional monomer or oligomer with solvents and other components.

The lower limit of the amount of the polyfunctional monomer or oligomer is preferably 5 parts by mass and the upper limit thereof is preferably 90 parts by mass, in 100 parts by mass in total of the resin having an imide skeleton in a backbone repeating unit and the polyfunctional monomer or oligomer. When the amount of the polyfunctional monomer or oligomer is within this range, the resulting resin composition can be more easily separated upon separation. To further increase the separability, the lower limit of the amount of the polyfunctional monomer or oligomer is more preferably 10 parts by mass, and the upper limit thereof is more preferably 50 parts by mass.

When the resin composition contains the resin containing no carbon-carbon double bond-containing reactive functional group and having an imide skeleton in a backbone repeating unit and the resin containing a carbon-carbon double bond-containing reactive functional group and having an imide skeleton in a backbone repeating unit, as the resin having an imide skeleton in a backbone repeating unit, and also contains the polyfunctional monomer or oligomer, the lower limit of the amount in total of the resin containing a carbon-carbon double bond-containing reactive functional group and having an imide skeleton in a backbone repeating unit and the polyfunctional monomer or oligomer is preferably 20 parts by mass and the upper limit thereof is preferably 80 parts by mass, in 100 parts by mass in total of the resin containing no carbon-carbon double bond-containing reactive functional group and having an imide skeleton in a backbone repeating unit, the resin containing a carbon-carbon double bond-containing reactive functional group and having an imide skeleton in a backbone repeating unit, and the polyfunctional monomer or oligomer. When the amount in total of the resin containing a carbon-carbon double bond-containing reactive functional group and having an imide skeleton in a backbone repeating unit and the polyfunctional monomer or oligomer is within this range, the resulting resin composition can be more easily separated upon separation. To further increase the separability, the lower limit of the amount in total of the resin containing a carbon-carbon double bond-containing reactive functional group and having an imide skeleton in a backbone repeating unit and the polyfunctional monomer or oligomer is more preferably 30 parts by mass, still more preferably 40 parts by mass, even more preferably 50 parts by mass and the upper limit thereof is more preferably 70 parts by mass.

The resin composition of the present invention preferably contains a compound containing a maleimide group. The presence of the compound containing a maleimide group further improves the heat resistance of the resulting resin composition.

The compound containing a maleimide group is preferably the polyfunctional monomer or oligomer that contains a maleimide group or a resin containing a maleimide group and having an imide skeleton in a backbone repeating unit. In other words, the resin composition of the present invention preferably contains a compound containing a maleimide group as the polyfunctional monomer or oligomer or contains a resin containing a maleimide group as the carbon-carbon double bond-containing reactive functional group in the resin containing a carbon-carbon double bond-containing reactive functional group and having an imide skeleton in a backbone repeating unit.

In particular, the resin composition of the present invention preferably contains, as the resin containing a maleimide group and having an imide skeleton in a backbone repeating unit, a resin containing a structural unit represented by the formula (1) and having a functional group containing a maleimide group at least either at an end or in a side chain. The polyfunctional monomer or oligomer that contains a maleimide group is preferably a bismaleimide compound.

The resin composition of the present invention preferably further contains a polymerization initiator. The polymerization initiator may be a thermal polymerization initiator or a photopolymerization initiator but is preferably a photopolymerization initiator.

The photopolymerization initiator used is, for example, activated by irradiation with light at a wavelength of 250 to 800 nm. In particular, the photopolymerization initiator preferably contains a compound having a molar absorption coefficient at 365 nm of 1 or greater, because such a photopolymerization initiator is less likely to overlap in absorption wavelength with the resin containing a carbon-carbon double bond-containing reactive functional group and having an imide skeleton in a backbone repeating unit or the polyfunctional monomer or oligomer, and is sufficiently activated when the resin composition is irradiated with light. The photopolymerization initiator more preferably contains a compound having a molar absorption coefficient at 365 nm of 200 or greater, still more preferably a compound having a molar absorption coefficient at 365 nm of 350 or greater. The upper limit of the molar absorption coefficient at 365 nm of the compound having a molar absorption coefficient at 365 nm of 1 or greater is not limited, but is practically 2,000.

Examples of the photopolymerization initiator include acetophenone derivatives, benzoin ether compounds, ketal derivatives, and phosphine oxide derivatives.

Examples of the acetophenone derivatives include methoxyacetophenone.

Examples of the benzoin ether compounds include benzoin propyl ether and benzoin butyl ether.

Examples of the ketal derivatives include benzyl dimethyl ketal and acetophenone diethyl ketal.

Examples of the phosphine oxide derivatives include diphenyl(2,4,6-trimethylbenzoyl)phosphine oxide.

Examples of the photopolymerization initiator further include bis(η5-cyclopentadienyl) titanocene derivative compounds, benzophenone, Michler's ketone, chlorothioxanthone, dodecylthioxanthone, dimethylthioxanthone, diethylthioxanthone, α-hydroxycyclohexyl phenyl ketone, and 2-hydroxymethyl phenyl propane.

These photopolymerization initiators may be used alone or in combination of two or more thereof.

The lower limit of the amount of the photopolymerization initiator is preferably 0.1 parts by mass and the upper limit thereof is preferably 10 parts by mass, relative to 100 parts by mass of a total of the resin having an imide skeleton in a backbone repeating unit and the polyfunctional monomer or oligomer. When the amount of the polymerization initiator is within this range, the resin composition as a whole can uniformly and quickly polymerize and crosslink when irradiated with light. The resulting increase in the modulus of elasticity greatly decreases adhesion, preventing a rise in adhesion or the generation of adhesive deposits upon separation. The lower limit of the amount of the polymerization initiator is more preferably 0.3 parts by mass, and the upper limit thereof is more preferably 3 parts by mass.

The resin composition of the present invention may further contain a gas generating agent. The resin composition containing the gas generating agent generates gas when irradiated with light to discharge the gas to the interface with the adherend. Thus, the adherend can be more easily separated without adhesive deposits even after heat treatment at high temperature of 300 °C or higher. In addition, even a thin adherend can be separated without damage thereto after heat treatment at high temperature of 300 °C or higher.

The gas generating agent preferably has a weight loss rate at 300 °C of 5% or less when heated from 30 °C to 300 °C at a heating rate of 10 °C/min in a nitrogen atmosphere in thermogravimetry-differential thermal analysis (TG-DTA) measurement. When the weight loss rate is 5% or less, the gas generating agent is less likely to decompose even during heat treatment at high temperature of 300 °C or higher, and the resulting resin composition has better heat resistance. In other words, a temporary fixing material produced using the resulting resin composition can further reduce the occurrence of detachment during heat treatment at high temperature and can further prevent a rise in adhesion or the generation of adhesive deposits upon separation.

The thermogravimetry-differential thermal analysis (TG-DTA) measurement can be performed using, for example, a TG-DTA device (“STA7200RV” produced by Hitachi High-Tech Science Corporation).

Examples of the gas generating agent include gas generating agents that generate gas when heated and gas generating agents that generate gas when irradiated with light. Among these, gas generating agents that generate gas when irradiated with light are preferred, and gas generating agents that generate gas when irradiated with UV light are more preferred.

Examples of the gas generating agent include tetrazole compounds or salts thereof, triazole compounds or salts thereof, azo compounds, azide compounds, xanthone acetic acid, and carbonates. These gas generating agents may be used alone or in combination of two or more thereof.

Among these, tetrazole compounds or salts thereof are preferred for their particularly high heat resistance.

The lower limit of the amount of the gas generating agent is preferably 5 parts by mass and the upper limit thereof is preferably 50 parts, relative to 100 parts by mass of a total of the resin having an imide skeleton in a backbone repeating unit and the polyfunctional monomer or oligomer. When the amount of the gas generating agent is within this range, a temporary fixing material produced using the resulting resin composition has particularly excellent separability. The lower limit of the amount of the gas generating agent is more preferably 8 parts by mass, and the upper limit thereof is more preferably 30 parts by mass.

The resin composition of the present invention may further contain an inorganic filler.

When containing the inorganic filler, a temporary fixing material produced using the resulting resin composition can further reduce detachment even during heat treatment at high temperature because the inorganic filler can reduce a decrease in the modulus of elasticity of the resulting resin composition at high temperature.

The inorganic filler may be, for example, an inorganic filler formed of at least one selected from the group consisting of oxides of silicon, titanium, aluminum, calcium, boron, magnesium, and zirconia, and composites of these. Preferred among these are silica and talc, which are commercial products and inexpensively and easily available.

The inorganic filler may be surface-modified. Examples of the modifying functional group used to surface-modify the inorganic filler include an alkylsilane group, a methacryloyl group, and a dimethylsiloxane group. Preferred among these is a dimethylsiloxane group, which has appropriate hydrophobicity.

The lower limit of the average particle size of the inorganic filler is preferably 5 nm, and the upper limit thereof is preferably 30 μm. When the average particle size of the inorganic filler is within this range, a temporary fixing material produced using the resulting resin composition can further reduce detachment during heat treatment at high temperature and can be separated by peel treatment upon separation. The lower limit of the average particle size of the inorganic filler is more preferably 10 nm, and the upper limit thereof is more preferably 20 μm. The lower limit is still more preferably 15 nm, and the upper limit is still more preferably 15 μm.

The average particle size is preferably a number average particle size. The average particle size can be measured by, for example, observing 50 random inorganic filler particles with an electron microscope or an optical microscope and calculating the average of the particle sizes of the inorganic filler particles, or by performing laser diffraction particle size distribution measurement.

The lower limit of the amount of the inorganic filler is preferably 1 part by mass and the upper limit thereof is preferably 20 parts by mass, relative to 100 parts by mass of a total of the resin having an imide skeleton in a backbone repeating unit and the polyfunctional monomer or oligomer. When the amount of the inorganic filler is within this range, a temporary fixing material produced using the resulting resin composition can further reduce detachment during heat treatment at high temperature and can be separated by peel treatment upon separation. The lower limit of the amount of the inorganic filler is more preferably 3 parts by mass, and the upper limit thereof is more preferably 15 parts by mass. The lower limit is still more preferably 5 parts by mass, and the upper limit is still more preferably 10 parts by mass.

The resin composition of the present invention may contain, for example, known additives such as photosensitizers, thermal stabilizers, antioxidants, antistatic agents, plasticizers, resins, surfactant, and waxes.

The resin composition of the present invention may be produced, for example, by a method including mixing the resin having an imide skeleton in a backbone repeating unit, the (meth)acrylic copolymer, and optional additives using a device such as a bead mill, an ultrasonic disperser, a homogenizer, a high-power disperser, or a roll mill.

The lower limit of the 10% weight loss temperature of the resin composition of the present invention is preferably 200 °C. When the 10% weight loss temperature is 200 °C or higher, a temporary fixing material produced using the resulting resin composition has better heat resistance. The lower limit of the 10% weight loss temperature is more preferably 220 °C, still more preferably 250 °C.

The preferable upper limit of the 10% weight loss temperature is not limited but is practically about 600 °C. When the temporary fixing material is curable as described later, the 5% weight loss temperature of a cured product of the temporary fixing material is preferably within the range.

The 10% weight loss temperature can be measured using a thermogravimetry-differential thermal analyzer. The 10% weight loss temperature can be specifically measured as follows.

First, the resin composition is weighed into an aluminum pan. When the resin composition is thermosetting or photocurable, the resin composition is cured by heating in an oven at 150 °C for 10 minutes or by irradiation with UV light at a wavelength of 365 nm at an intensity of 70 mW/cm² for 300 seconds, and the resulting cured product is weighed into an aluminum pan. Next, the aluminum pan is set in a thermogravimetry-differential thermal analyzer. The measurement sample is heated from 30 °C to 500 °C at a heating rate of 10 °C/min in a nitrogen atmosphere, and the temperature at which a 10% weight loss occurs is measured as the 10% weight loss temperature. STA7200RV (Hitachi High-Tech Science Corporation) can be used as the thermogravimetry-differential thermal analyzer.

When the resin composition of the present invention is thermosetting or photocurable, the lower limit of the gel fraction after curing of the resin composition of the present invention is preferably 70% by mass and the upper limit thereof is preferably 95% by mass. When the gel fraction after curing is within the range, a temporary fixing material produced using the resulting resin composition can be more easily separated upon separation from the adherend. The lower limit of the gel fraction after curing is more preferably 75% by mass, and the upper limit thereof is more preferably 90% by mass.

For measurement of the gel fraction after curing, the resin composition is cured by irradiation with UV light at 365 nm at an intensity of 70 mW/cm² for 300 seconds in the case where the resin composition is photocurable or by heating at 150 °C for 10 minutes in the case where the resin composition is thermosetting, and then the gel fraction is measured by the following method.

First, the cured resin composition is cut into a flat rectangular specimen having a size of 50 mm×100 mm. The specimen obtained is immersed in toluene at 23 °C for 24 hours, then taken out of the toluene, and dried at 110 °C for one hour. The mass of the dried specimen is measured, and the gel fraction is calculated using the following equation. No separator or the like to protect the temporary fixing material is stacked on the specimen. When the temporary fixing material includes no substrate, W₀ is set to 0 (W₀=0).

Gel fraction (% by mass)=100×(W₂−W₀)/(W₁−W₀)

(W₀: the mass of the substrate, W₁: the mass of the specimen before immersion, W₂: the mass of the specimen after immersion and drying)

The resin composition of the present invention is favorably used for a temporary fixing material for electronic components. The present invention also encompasses a temporary fixing material containing the resin composition of the present invention.

The temporary fixing material of the present invention may have any form, such as a liquid or paste form or a form including an adhesive layer containing the resin composition of the present invention. In particular, the temporary fixing material preferably includes an adhesive layer containing the resin composition of the present invention. When including the adhesive layer, the temporary fixing material is preferably a tape-like material.

When including the adhesive layer, the temporary fixing material may include the adhesive layer(s) on one or both surfaces of a substrate, or may not include a substrate. The absence of the substrate eliminates the need for selecting a substrate having both light transmission and heat resistance, leading to a less expensive, simply structured temporary fixing material. When including the substrate, the temporary fixing material of the present invention has better handleability.

When the temporary fixing material includes the substrate, examples of the substrate include resin sheets formed of resins such as acrylic, olefin, polycarbonate, vinyl chloride, ABS, polyethylene terephthalate (PET), polyethylene naphthalate (PEN), nylon, urethane, polyimide, polyether ether ketone (PEEK), and polyamide (PA). A resin sheet with high light transmission is favorably used. The substrate may be a sheet having a mesh-like structure, a perforated sheet, or glass.

To increase the light transmission and the flexibility, the lower limit of the thickness of the substrate is preferably 5 μm, more preferably 10 μm. The upper limit thereof is preferably 150 μm, more preferably 100 μm.

The temporary fixing material of the present invention may be produced by any method. For example, a PET film one surface of which has been release-treated is provided. The resin composition obtained by the above-described method is applied to the release-treated surface of the PET film with, for example, an applicator and dried to form an adhesive layer containing the resin composition. Another PET film one surface of which has been release-treated is placed on the adhesive layer such that the release-treated surface thereof faces the adhesive layer, whereby a temporary fixing material including release-treated PET films and no substrate can be obtained as a temporary fixing material in the form including an adhesive layer.

Alternatively, after formation of an adhesive layer by the above method, a substrate is placed on the adhesive layer such that the substrate faces the adhesive layer, whereby a temporary fixing material including a release-treated PET film and a substrate can be obtained.

When the temporary fixing material of the present invention includes the adhesive layer, the lower limit of the thickness of the whole temporary fixing material of the present invention is preferably 5 μm and the upper limit thereof is preferably 550 μm. When the temporary fixing material has a thickness of 5 μm or greater, the whole temporary fixing material can have sufficient initial pressure-sensitive or heat-sensitive adhesion. When the whole temporary fixing material has a thickness of 550 μm or less, the temporary fixing material can exhibit high flexibility, and thus can exhibit high conformability to adherends with irregularities and can be more easily separated upon separation. The lower limit of the thickness of the whole temporary fixing material is more preferably 10 μm, still more preferably 20 μm, further preferably 30 μm. The upper limit of the thickness of the whole temporary fixing material is more preferably 400 μm, still more preferably 300 μm, further preferably 200 μm, particularly preferably 150 μm.

The lower limit of the initial adhesion to polyimide at 25 °C of the temporary fixing material of the present invention is preferably 0.1 N/inch and the upper limit thereof is preferably 1.5 N/inch. When the initial adhesion to polyimide at 25 °C is within this range, the temporary fixing material of the present invention can further prevent a rise in adhesion to the adherend having polyimide on its surface after heat treatment at high temperature or the generation of adhesive deposits upon separation and can be more easily separated from the adherend having polyimide on its surface upon separation. The lower limit of the initial adhesion to polyimide at 25 °C is more preferably 0.2 N/inch and the upper limit thereof is more preferably 1.2 N/inch.

The lower limit of the adhesion to polyimide at 25 °C of the temporary fixing material of the present invention after heating at 250 °C for two hours is preferably 0.01 N/inch and the upper limit thereof is preferably 1.5 N/inch. When the adhesion to polyimide at 25 °C after heating at 250 °C for two hours is within this range, the temporary fixing material of the present invention can further prevent a rise in adhesion to the adherend having polyimide on its surface after heat treatment at high temperature or the generation of adhesive deposits upon separation and can be more easily separated from the adherend having polyimide on its surface upon separation. The lower limit of the adhesion to polyimide at 25 °C after heating at 250 °C for two hours is more preferably 0.1 N/inch and the upper limit thereof is more preferably 1 N/inch.

The adhesion to polyimide can be measured by the following method.

Specifically, the temporary fixing material is laminated to polyimide using a laminator, whereby a laminate was obtained. The polyimide used may be, for example, Upilex (UBE Corporation) or Kapton (Du Pont-Toray Co., Ltd.). The laminator used may be, for example, Leon 13DX (Lami Corporation Inc., speed memory: 5). When the temporally fixing material is produced using a thermosetting or photocurable resin composition, the temporary fixing material is cured by heating in an oven at 150 °C for 10 minutes or by irradiation with UV light at a wavelength of 365 nm at an intensity of 70 mW/cm² for 300 seconds, whereby a laminate is obtained. A peeling test is performed on the resulting laminate using a tensile tester under the conditions of 25 °C, a tensile angle of 30°, and a tensile speed of 300 mm/min, whereby the initial adhesion to polyimide at 25 °C can be measured. The tensile tester used may be a versatile peel analyzer VPA-2S (Kyowa Interface Science Co., Ltd.). For the adhesion to polyimide at 25 °C after heating at 250 °C for two hours, the resulting laminate is heated at 250 °C for two hours and then similarly subjected to the measurement of the adhesion to polyimide.

The temporary fixing material of the present invention can prevent a rise in adhesion to the adherend after heat treatment at high temperature or the generation of adhesive deposits upon separation and can be easily separated upon separation from the adherend. Thus, the temporary fixing material of the present invention can be suitably used to protect and temporarily fix adherends to be subjected to heat treatment at high temperature, particularly adherends having polyimide on their surfaces. In particular, for easier handling and less breakage of electronic components (e.g., semiconductors) during processing of the electronic components, the temporary fixing material may be suitably used to fix electronic components to supports, or the temporary fixing material may be suitably bonded to electronic components to protect the components.

The present invention also encompasses a method for producing an electronic component, including: a temporary fixing step of temporarily fixing an electronic component to the temporary fixing material of the present invention; a heat treatment step of heat-treating the electronic component; and a separation step of separating the electronic component from the temporary fixing material of the present invention. When the temporary fixing material of the present invention is produced using a thermosetting or photocurable resin composition, the method preferably further includes, between the temporary fixing step and the heat treatment step, a curing step of curing the temporary fixing material. Performing the curing step between the temporary fixing step and the heat treatment step allows the temporary fixing material to exhibit better heat resistance.

### Advantageous Effects of Invention

The present invention can provide a resin composition that can reduce the occurrence of voids and partial detachment during heat treatment and is easily separable after the heat treatment. The present invention also can provide a temporary fixing material containing the resin composition and a method for producing an electronic component using the temporary fixing material.

### DESCRIPTION OF EMBODIMENTS

Embodiments of the present invention are more specifically described in the following with reference to, but not limited to, examples.

### Synthesis Example 1

A 500-mL round flask with a Teflon (®) stirrer placed therein was charged with 250 mL of toluene. Then, 31.9 g (0.06 mol) of dimer diamine (produced by Croda, “Priamine 1075”), 5.5 g (0.015 mol) of 2,2-bis(3-amino-4-hydroxyphenyl)-hexafluoropropane, and 39 g (0.0765 mol) of 4,4′-(4,4′-isopropylidenediphenoxy)diphthalic anhydride were added in this order. A Dean-Stark trap and a condenser were fitted to the flask and the resulting mixture was refluxed for six hours, and then cooled to room temperature. Thus, a brown resin (maleimide group-free PI (A)) containing a structural unit represented by the following formula (5-1) and a structural unit represented by the following formula (5-2), containing no maleimide group, and having an imide skeleton in a backbone repeating unit was obtained.

The weight average molecular weight of the obtained maleimide group-free PI (A) was 78,000, as determined by gel permeation chromatography (GPC, device name: Acquity APC system (produced by Waters)) in which the eluent used was THF and the column used was HR-MB-M (trade name, produced by Waters Corporation, 6.0×150 mm).

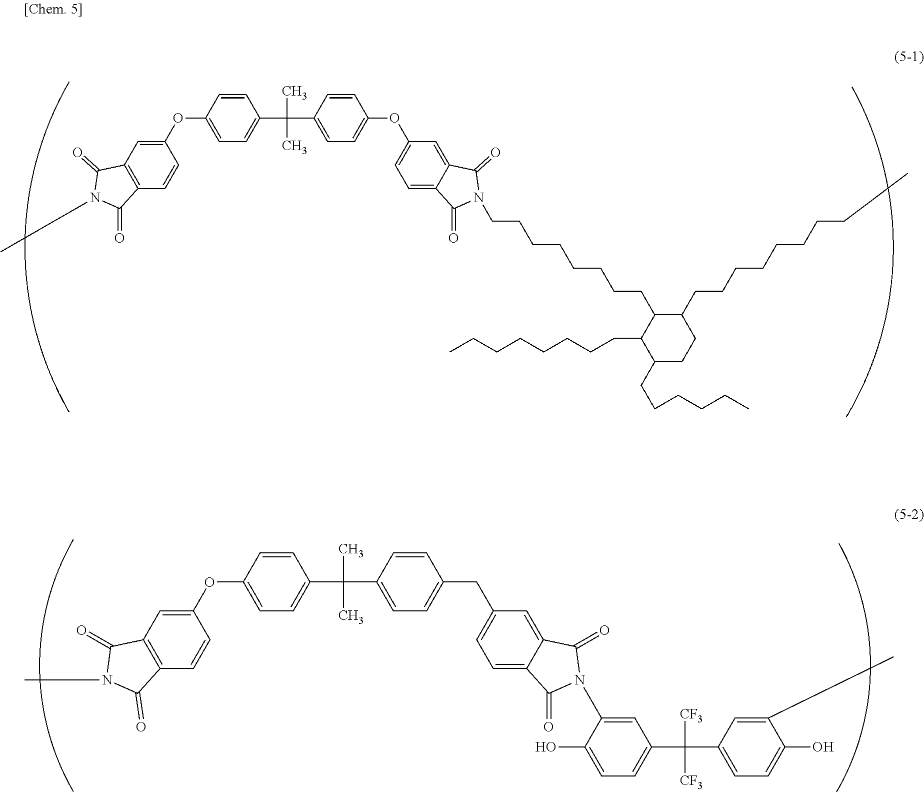

### Synthesis Example 2

A 500-mL round flask with a Teflon (®) stirrer placed therein was charged with 250 mL of toluene. Then, 35 g (0.35 mol) of triethylamine and 35 g (0.36 mol) of methanesulfonic anhydride were added, and the mixture was stirred to form salt. After stirring for 10 minutes, 56 g (0.1 mol) of dimer diamine (produced by Croda, Priamine 1075) and 19.1 g (0.09 mol) of pyromellitic anhydride were added in this order. A Dean-Stark trap and a condenser were fitted to the flask and the mixture was refluxed for two hours for formation of amine-terminated diimide. After cooling to room temperature or lower, the reaction product was blended with 12.8 g (0.13 mol) of maleic anhydride and then with 5 g (0.05 mol) of methanesulfonic anhydride. The resulting mixture was further refluxed for 12 hours and then cooled to room temperature. To the flask was added 300 mL of toluene, and the flask was allowed to stand still for phase separation. The lower layer containing impurities was removed. The obtained solution was filtered through a glass frit funnel filled with silica gel, followed by removal of the solvent in vacuum. Thus, an amber wax-like resin (maleimide group-containing PI) represented by the following formula (6), containing maleimide groups at both ends and having an imide skeleton in a backbone repeating unit, was obtained.

The weight average molecular weight of the obtained maleimide group-containing PI was 5,000, as determined by gel permeation chromatography (GPC, device name: Acquity APC system (produced by Waters)) in which the eluent used was THE and the column used was HR-MB-M (trade name, produced by Waters Corporation, 6.0×150 mm).

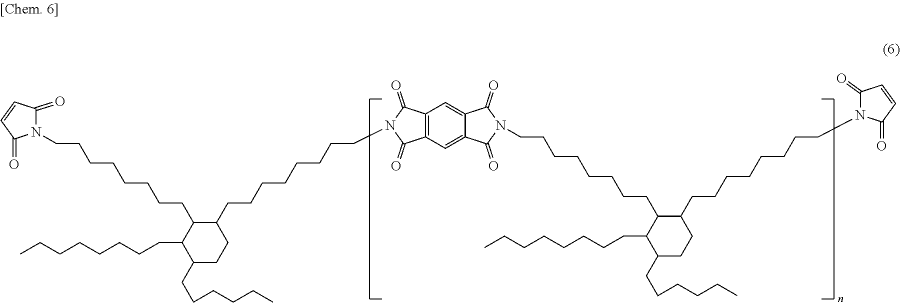

In the formula (6), n is the number of repetitions.

### Synthesis Example 3

A 500-mL round flask with a Teflon (®) stirrer placed therein was charged with 250 mL of toluene. Then, 56 g (0.1 mol) of dimer diamine (produced by Croda, Priamine 1075) and 19.6 g (0.2 mol) of maleic anhydride were added, and subsequently 5 g of methanesulfonic anhydride was added. The resulting solution was refluxed for 12 hours and then cooled to room temperature. To the flask was added 300 mL of toluene, and the flask was allowed to stand still for phase separation. The lower layer containing impurities was removed. The obtained solution was filtered through a glass frit funnel filled with silica gel, followed by removal of the solvent in vacuum. Thus, a brown, liquid bismaleimide monomer (polyfunctional monomer) represented by the following formula (7) was obtained.

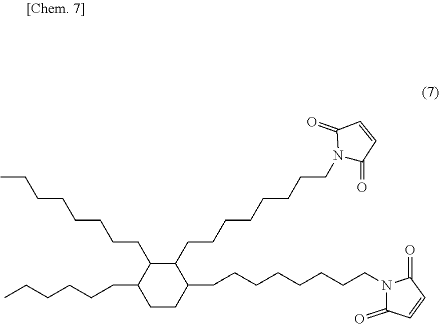 [SMILES: CCCCCCCCC1C(CCCCCC)CCC(CCCCCCCCN2C(=O)C=CC2=O)C1CCCCCCCCN1C(=O)C=CC1=O]

### Synthesis Example 4

A reactor was charged with ethyl acetate as a polymerization solvent. After bubbling with nitrogen, the reactor was heated with an inflow of nitrogen to initiate reflux. Then, 0.1 parts by mass of azobisisobutylonitrile as a polymerization initiator was diluted 10 times with ethyl acetate to prepare a polymerization initiator solution. The polymerization initiator solution was fed to the reactor, and 100 parts by mass in total of monomer components in Table 1 was dropwise added over two hours. After completion of the dropwise addition, a polymerization initiator solution prepared by diluting 0.1 parts by mass of azobisisobutylonitrile as a polymerization initiator 10 times with ethyl acetate was again fed to the reactor. The polymerization reaction was carried out for the time shown in Table 1, and 2,2-diphenyl-1-(2,4,6-trinitrophenyl)iminoazanium (DPPH) was added thereto, whereby solutions containing (meth)acrylic copolymers A to K were obtained. The solvent was removed from the resulting solutions to obtain viscous liquids containing (meth)acrylic copolymers A to K with a solid content of 50% to 98%.

The weight average molecular weights of the (meth)acrylic copolymers A to K were measured by the same method as that used in Synthesis Examples 1 and 2. Table 1 shows the results.

The glass transition temperatures of the (meth)acrylic copolymers A to K were determined by dividing the proportion by the glass transition temperature for each monomer component constituting each (meth)acrylic copolymer ((proportion of monomer component (mol %))/(glass transition temperature (K) of monomer component)) and calculating the reciprocal of the sum of the obtained values of all monomer components constituting the (meth)acrylic copolymer. Table 1 shows the results.

TABLE 1

| | | Monomer composition (mol %) | | | | |
|---|---|---|---|---|---|---|
| | | Branched alkyl (meth)acrylate | | | Linear alkyl (meth)acrylate | |
| | | Isostearyl acrylate | 2-Ethylhexyl acrylate | Isobutyl acrylate | Lauryl acrylate | n-Butyl acrylate |
| | | (alkyl group C18) | (Alkyl group C8) | (Alkyl groupC4) | (Alkyl group C12) | (Alkyl groupC4) |
| (Meth)acrylic | (Meth)acrylic copolymer A | 50 | — | — | 50 | — |
| copolymer | (Meth)acrylic copolymer B | 50 | — | — | — | — |
| | (Meth)acrylic copolymer C | — | — | 50 | 50 | — |
| | (Meth)acrylic copolymer D | — | — | 50 | — | — |
| | (Meth)acrylic copolymer E | — | 80 | — | — | 20 |
| | (Meth)acrylic copolymer F | — | 20 | — | — | 80 |
| | (Meth)acrylic copolymer G | 50 | — | — | 50 | — |
| | (Meth)acrylic copolymer H | — | — | 50 | — | — |
| | (Meth)acrylic copolymer I | — | — | 50 | — | 20 |
| | (Meth)acrylic copolymer J | — | 40 | — | — | 60 |
| | (Meth)acrylic copolymer K | — | 40 | — | — | 50 |

| | | Monomer composition (mol %) | | | | | |
|---|---|---|---|---|---|---|---|
| | | | | Polar functional group- | | | Weight |
| | | Linear alkyl (meth)acrylate | | containing monomer | Polymer- | Glass | average |
| | | | Methyl | 4-Hydroxybutyl acrylate | ization | transition | molecular |
| | | Ethyl acrylate | methacrylate | (Hydroxy group- | time | temperature | weight |
| | | (Alkyl group C2) | (Alkyl group C1) | containing monomer) | (min) | (°C) | (Mw) |
| (Meth)acrylic | (Meth)acrylic copolymer A | — | — | — | 60 | −20.5 | 8500 |
| copolymer | (Meth)acrylic copolymer B | 50 | — | — | 60 | −19.0 | 6000 |
| | (Meth)acrylic copolymer C | — | — | — | 60 | −24.5 | 5000 |
| | (Meth)acrylic copolymer D | 50 | — | — | 120 | −23.0 | 10000 |
| | (Meth)acrylic copolymer E | — | — | — | 90 | −67.2 | 15000 |
| | (Meth)acrylic copolymer F | — | — | — | 60 | −58.2 | 6500 |
| | (Meth)acrylic copolymer G | — | — | — | 120 | −20.5 | 20000 |
| | (Meth)acrylic copolymer H | 50 | — | — | 60 | −23.0 | 2000 |
| | (Meth)acrylic copolymer I | — | 30 | — | 60 | −5.3 | 9000 |
| | (Meth)acrylic copolymer J | — | — | — | 60 | −61.3 | 7000 |
| | (Meth)acrylic copolymer K | — | — | 10 | 60 | −59.9 | 7500 |

### Examples 1 to 16 and Comparative Examples 1 to 3

A toluene solution of a resin composition was prepared by adding the materials shown in Table 2 to 150 mL of toluene.

A 50-μm-thick PET film one surface of which was release-treated was provided. The obtained toluene solution of a resin composition was applied with a doctor knife to the release-treated surface to a dry film thickness of 50 μm, and the applied solution was dried by heating at 110 °C for ten minutes. Next, another PET release film was attached to the dried film such that the release-treated surface of the PET film faces the resin composition side surface. The dried film was allowed to stand still at 40 °C for three days. Thus, a temporary fixing material with PET release films on both surfaces was obtained.

### (10% Weight Loss Temperature)

From the resulting temporary fixing material with PET release films on both surfaces, the PET release films on both surfaces were separated, and 10 mg of the temporary fixing material was weighed into an aluminum pan. In the case of the temporary fixing material with PET release films on both surfaces obtained in Example 12, 13, or 15, it was irradiated with UV light at a wavelength of 365 nm and an intensity of 70 mW/cm² for 300 seconds to be cured after separation of the PET release films on both surfaces, and 10 mg thereof was weighed into an aluminum pan. The aluminum pan was set in a thermogravimetry-differential thermal analyzer (produced by Hitachi High-Tech Science Corporation, “STA7200”). The measurement sample was heated from 25 °C to 500 °C at a heating rate of 10 °C/min in a nitrogen atmosphere, and the temperature at which a 10% weight loss of the temporary fixing material or cured temporary fixing material occurred was measured as the 10% weight loss temperature. Table 2 shows the results.

(Initial Adhesion to Polyimide at 25 °C, Adhesion to Polyimide at 25 °C after Heating at 250 °C for Two Hours)

The resulting temporary fixing material with PET release films on both surfaces was cut to a width of 1 inch. Next, one PET release film was separated from the temporary fixing material with PET release films on both surfaces, and the temporary fixing material was laminated to a polyimide film with a laminator, whereby a laminate was obtained. In the case of the temporary fixing material with PET release films on both surfaces obtained in Example 12 or 13, it was irradiated with UV light from the temporary fixing material side at a wavelength of 365 nm and an intensity of 70 mW/cm² for 300 seconds using an ultra-high pressure mercury lamp to be cured after lamination to a polyimide film adherend, whereby a laminate was obtained. The polyimide adherend used was a 125-μm-thick Upilex (UBE Corporation) the entire surface of which was attached to a 1.5-mm-thick SUS plate with double-sided tape. The laminator used was Leon 13DX (Lami Corporation Inc., speed memory: 5). A peeling test was performed on the resulting laminate using a tensile tester under the conditions of 100 °C, a tensile angle of 90°, and a tensile speed of 300 mm/min, whereby the initial adhesion (N/inch) of the temporary fixing material to polyimide was measured. The tensile tester used was a versatile peel analyzer VPA-2S (Kyowa Interface Science Co., Ltd.). A cured temporary fixing material prepared similarly was heated on a hot plate (produced by As One Corporation, “ND-3HA”) at 250 °C for two hours, and the adhesion of the temporary fixing material to polyimide at 25 °C was similarly measured. Table 2 shows the results.

(Gel Fraction after Curing)

In the case of the temporary fixing material with PET release films on both surfaces obtained in Example 12, 13, or 15, it was irradiated with UV light at a wavelength of 365 nm and an intensity of 70 mW/cm² for 300 seconds after separation of the PET release films on both surfaces so that the resin composition was cured. The cured temporary fixing material was cut to obtain a 50 mm×100 mm flat rectangular specimen. The specimen obtained was immersed in toluene at 23 °C for 24 hours, then taken out of the toluene, and dried at 110 °C for one hour. The mass of the dried specimen was measured, and the gel fraction was calculated using the following equation. Table 2 shows the results.

Gel fraction (% by mass)=100×(W₂−W₀)/(W₁−W₀)

(W₀: the mass of the substrate, W₁: the mass of the specimen before immersion, W₂: the mass of the specimen after immersion and drying)

### <Evaluation>

The temporary fixing materials with PET release films obtained in the examples and the comparative examples were evaluated by the following methods. Table 2 shows the results.

### (Heat Resistance)

The resulting temporary fixing material with PET release films on both surfaces was cut to a circular shape with a diameter of 200 mm. Next, one PET release film was separated from the resulting temporary fixing material with PET release films on both surfaces, and the temporary fixing material was attached to a silicon wafer (diameter: 200 mm, thickness: 700 μm) having a polyimide film on its surface with a vacuum laminator such that the temporary fixing material faces the polyimide film. The vacuum laminator used was ATM-812M (produced by Takatori Corporation). Next, the other PET release film was separated, and glass (diameter: 200 mm, thickness: 600 μm, produced by Schott, “Tempax”) was attached with a vacuum laminator to a surface opposite to the surface with the polyimide film. In the case of the temporary fixing material with PET release films on both surfaces obtained in Example 12 or 13, it was irradiated, after attachment of glass, with UV light from the glass side at a wavelength of 365 nm and an intensity of 70 mW/cm² for 300 seconds using an ultra-high pressure mercury lamp to be cured, whereby a laminate was obtained. The resulting laminate was heated on a hot plate (produced by As One Corporation, “ND-3HA”) at 250 °C for one hour.

Heat resistance evaluation was performed based on the following criteria: a case where no detachment was observed was rated “∘∘ (Excellent)”; a case where the area suffering detachment was less than 5% in the entire attached area was rated “∘ (Good)”; a case where the area suffering detachment was 5% or greater in the entire attached area was rated “x (Poor)”.

### (Adhesive Deposits)

(Wafer without Bumps)

A laminate was obtained as in “(Heat resistance)”. The resulting laminate was heated on a hot plate (produced by As One Corporation, “ND-3HA”) at 250 °C for one hour. The entire glass surface of the naturally cooled laminate was irradiated with pulsed laser at a wavelength of 355 nm, an irradiation energy density of 700 mJ/cm², and a frequency of 60 kHz from the glass side. After separation of the glass, the temporary fixing material was subjected to a 180° peel test with a tensile tester (produced by Shimadzu Corporation, “AG-IS”) under the conditions of 25 °C and a tensile speed of 300 mm/min.

Adhesive deposits evaluation was performed based on the following criteria: a case where no adhesive deposits were observed on the polyimide film surface of the silicon wafer was rated “∘∘ (Excellent)”; a case where the area suffering adhesive deposits was less than 5% in the entire attached area was rated “∘ (Good)”; a case where the area suffering adhesive deposits was 5% or greater in the entire attached area was rated “x (Poor)”.

(Wafer with Bumps)

A laminate was obtained as in “(Heat resistance)”, except that the silicon wafer (diameter: 200 mm, thickness: 700 μm) having a polyimide film on its surface was replaced by a wafer with a test pattern having a PBO film on its surface (produced by Waltz Co., Ltd., “WALTS-TEG FBW100A-0001JY”, height of Cu pillars: 35 μm, height of SnAg on Cu pillars: 15 μm) and that the temporary fixing material with PET release films on both surfaces was attached to the surface with Cu pillars of the wafer. The resulting laminate was heated on a hot plate (produced by As One Corporation, “ND-3HA”) at 250 °C for one hour. The entire glass surface of the naturally cooled laminate was irradiated with pulsed laser at a wavelength of 355 nm, an irradiation energy density of 700 mJ/cm², and a frequency of 60 kHz from the glass side. After separation of the glass, the temporary fixing material was separated from the wafer with a test pattern with a tensile tester (produced by Shimadzu Corporation, “AG-IS”) under the conditions of 25 °C and a tensile speed of 300 mm/min. Adhesive deposits evaluation was performed based on the following criteria: a case where no adhesive deposits were observed on the surface of the wafer with a test pattern after separation of the temporary fixing material was rated “∘∘ (Excellent)”; a case where the area suffering adhesive deposits was less than 5% in the entire attached area was rated “∘ (Good)”; a case where the area suffering adhesive deposits was 5% or greater in the entire attached area was rated “x (Poor)”.

### (Bump Deformation, Cracks)

Bump deformation/cracks evaluation was performed in the evaluation in “(Adhesive deposits) (Wafer with bumps)” based on the following criteria: a case where the rate of generation of bump deformation/cracks on the surface of the wafer with a test pattern after separation of the temporary fixing material was less than 1% was rated “∘∘ (Excellent)”; a case where the rate of generation of bump deformation/cracks was 1% or greater and less than 10% was rated “∘ (Good)”; a case where the rate of generation of bump deformation/cracks was 10% or greater was rated “x (Poor)”.

TABLE 2

| | | | Example | | | | | | | | | |
|---|---|---|---|---|---|---|---|---|---|---|---|---|
| | | | 1 | 2 | 3 | 4 | 5 | 6 | 7 | 8 | 9 | 10 |
| Composition | Maleimide group-free PI | | 100 | 100 | 100 | 100 | 100 | 100 | 100 | 100 | 100 | 100 |
| (Parts by | Maleimide group-containing PI | | — | — | — | — | — | — | — | — | — | — |
| mass) | Bismaleimide monomer | | — | — | — | — | — | — | — | — | — | — |
| | (Meth)acrylic | (Meth)acrylic copolymer A | 20 | 10 | — | — | — | — | — | — | — | — |
| | copolymer | (Meth)acrylic copolymer B | — | — | 10 | — | — | — | — | — | — | — |
| | | (Meth)acrylic copolymer C | — | — | — | 10 | — | — | — | — | — | — |
| | | (Meth)acrylic copolymer D | — | — | — | — | 10 | — | — | — | — | — |
| | | (Meth)acrylic copolymer E | — | — | — | — | — | 10 | — | — | — | — |
| | | (Meth)acrylic copolymer F | — | — | — | — | — | — | 10 | — | — | — |
| | | (Meth)acrylic copolymer G | — | — | — | — | — | — | — | 10 | — | — |
| | | (Meth)acrylic copolymer H | — | — | — | — | — | — | — | — | 10 | — |
| | | (Meth)acrylic copolymer I | — | — | — | — | — | — | — | — | — | 10 |
| | | (Meth)acrylic copolymer J | — | — | — | — | — | — | — | — | — | — |
| | | (Meth)acrylic copolymer K | — | — | — | — | — | — | — | — | — | — |
| | Silicone compound | EBECRYL 350 | — | — | — | — | — | — | — | — | — | — |
| | | (Daicel-Allnex Ltd.) | | | | | | | | | | |
| | Fluorine compound | MEGAFAC RS-56 | — | — | — | — | — | — | — | — | — | — |
| | | (DIC Corporation) | | | | | | | | | | |
| | Photopolymerization | Diphenyl(2,4,6-trimethyl- | — | — | — | — | — | — | — | — | — | — |
| | initiator | benzoyl)phosphine oxide | | | | | | | | | | |
| | | (IGM Resins, “Omnirad TPO H”) | | | | | | | | | | |
| 10% weight loss temperature | | | 280 | 290 | 250 | 260 | 210 | 220 | 230 | 290 | 220 | 260 |
| (°C) | | | | | | | | | | | | |
| Initial adhesion to polyimide at 25 °C | | | 1.2 | 2.3 | 1.8 | 1.7 | 1.1 | 2.4 | 2.5 | 2.8 | 1.0 | 3.1 |
| (N/inch) | | | | | | | | | | | | |
| Adhesion to polyimide at 25° after heating | | | 0.8 | 1.5 | 1.3 | 1.4 | 1.3 | 1.1 | 1.4 | 0.6 | 0.6 | 0.5 |
| at 250 °C for two hours (N/inch) | | | | | | | | | | | | |
| Gel fraction after curing | | | — | — | — | — | — | — | — | — | — | — |
| (% by mass) | | | | | | | | | | | | |
| Evaluation | Heat resistance | | ∘∘ | ∘∘ | ∘∘ | ∘∘ | ∘ | ∘ | ∘ | ∘∘ | ∘ | ∘∘ |
| | Adhesive deposits | Wafer without bumps | ∘ | ∘ | ∘ | ∘ | ∘∘ | ∘ | ∘ | ∘ | ∘∘ | ∘∘ |
| | | Wafer with bumps | ∘ | ∘ | ∘∘ | ∘∘ | ∘ | ∘ | ∘ | ∘ | ∘ | ∘ |

| | | | | | | | | | | |
|---|---|---|---|---|---|---|---|---|---|---|
| Bump deformation/cracks | ∘∘ | ∘∘ | ∘∘ | ∘∘ | ∘∘ | ∘∘ | ∘∘ | ∘∘ | ∘∘ | ∘∘ |

| | | | | | | | | Comparative | | |
|---|---|---|---|---|---|---|---|---|---|---|
| | | Example | | | | | | Example | | |
| | | 11 | 12 | 13 | 14 | 15 | 16 | 1 | 2 | 3 |
| Composition | Maleimide group-free PI | 100 | — | — | 100 | — | 100 | 100 | 100 | 100 |
| (Parts by | Maleimide group-containing PI | — | 100 | 50 | — | 50 | — | — | — | — |
| mass) | Bismaleimide monomer | — | — | 50 | — | 50 | — | — | — | — |

| | | | | | | | | | | |
|---|---|---|---|---|---|---|---|---|---|---|
| (Meth)acrylic | (Meth)acrylic copolymer A | — | — | — | — | — | — | — | — | — |
| copolymer | (Meth)acrylic copolymer B | — | — | — | — | — | — | — | — | — |
| | (Meth)acrylic copolymer C | — | — | — | — | — | — | — | — | — |
| | (Meth)acrylic copolymer D | — | — | — | — | — | — | — | — | — |
| | (Meth)acrylic copolymer E | — | — | — | — | — | — | — | — | — |
| | (Meth)acrylic copolymer F | — | — | — | — | 10 | — | — | — | — |
| | (Meth)acrylic copolymer G | — | — | — | — | — | — | — | — | — |
| | (Meth)acrylic copolymer H | — | — | — | — | — | — | — | — | — |
| | (Meth)acrylic copolymer I | — | — | — | — | — | — | — | — | — |
| | (Meth)acrylic copolymer J | 10 | 10 | 10 | 0.5 | — | — | — | — | — |
| | (Meth)acrylic copolymer K | — | — | — | — | — | — | — | — | — |
| Silicone compound | EBECRYL 350 | — | — | — | — | — | — | 10 | — | — |
| | (Daicel-Allnex Ltd.) | | | | | | | | | |
| Fluorine compound | MEGAFAC RS-56 | — | — | — | — | — | — | — | — | 10 |
| | (DIC Corporation) | | | | | | | | | |
| Photopolymerization | Diphenyl(2,4,6-trimethyl- | — | 1 | 1 | — | 1 | — | — | — | — |
| initiator | benzoyl)phosphine oxide | | | | | | | | | |
| | (IGM Resins, “Omnirad TPO H”) | | | | | | | | | |

| 10% weight loss temperature | | 230 | 250 | 260 | 300 | 250 | 240 | 250 | 300 | 260 |
|---|---|---|---|---|---|---|---|---|---|---|
| (°C) | | | | | | | | | | |
| Initial adhesion to polyimide at 25 °C | | 0.8 | 0.9 | 0.7 | 1.5 | 2.1 | 0.7 | 1.6 | 5.8 | 2.0 |
| (N/inch) | | | | | | | | | | |
| Adhesion to polyimide at 25° after heating | | 0.2 | 0.3 | 0.3 | 1.1 | 1.1 | 0.2 | 2.5 | 5.4 | 2.7 |
| at 250 °C for two hours (N/inch) | | | | | | | | | | |
| Gel fraction after curing | | — | 89 | 91 | — | 91 | — | — | — | — |
| (% by mass) | | | | | | | | | | |
| Evaluation | Heat resistance | ∘∘ | ∘∘ | ∘∘ | ∘∘ | ∘∘ | ∘∘ | ∘ | ∘ | ∘ |

| | | | | | | | | | | |
|---|---|---|---|---|---|---|---|---|---|---|
| Adhesive deposits | Wafer without bumps | ∘∘ | ∘∘ | ∘∘ | ∘ | ∘∘ | ∘∘ | x | x | x |
| | Wafer with bumps | ∘∘ | ∘∘ | ∘∘ | ∘ | ∘∘ | ∘∘ | x | x | x |

| | | | | | | | | | |
|---|---|---|---|---|---|---|---|---|---|
| Bump deformation/cracks | ∘∘ | ∘∘ | ∘∘ | ∘ | ∘∘ | ∘∘ | ∘ | x | ∘ |

### INDUSTRIAL APPLICABILITY

The present invention can provide a resin composition that can reduce the occurrence of voids and partial detachment during heat treatment and is easily separable after the heat treatment. The present invention also can provide a temporary fixing material containing the resin composition and a method for producing an electronic component using the temporary fixing material.

1. A resin composition comprising:
a resin having an imide skeleton in a backbone repeating unit; and
a (meth)acrylic copolymer.

2. The resin composition according to claim 1,
wherein the (meth)acrylic copolymer contains a structural unit derived from a branched alkyl (meth)acrylate.

3. The resin composition according to claim 2,
wherein the (meth)acrylic copolymer contains the structural unit derived from a branched alkyl (meth)acrylate in a proportion of 20 mol % or greater and 80 mol % or less.

4. The resin composition according to claim 1,
wherein the (meth)acrylic copolymer contains a structural unit derived from an alkyl(meth)acrylate containing an alkyl group with a carbon number of 2 or greater and 7 or less and a structural unit derived from an alkyl (meth)acrylate containing an alkyl group with a carbon number of 8 or greater, and the (meth)acrylic copolymer contains the structural unit derived from an alkyl (meth)acrylate containing an alkyl group with a carbon number of 2 or greater and 7 or less in a proportion of 20 mol % or greater and 80 mol % or less.

5. The resin composition according to claim 1,
wherein the (meth)acrylic copolymer contains no carbon-carbon double bond-containing reactive functional group.

6. The resin composition according to claim 1,
wherein the (meth)acrylic copolymer has a molecular weight of 2,000 or greater and 20,000 or less.

7. The resin composition according to claim 1,
wherein the (meth)acrylic copolymer has a glass transition temperature of −70 °C or higher and −5 °C or lower.

8. The resin composition according to claim 1,
wherein the resin having an imide skeleton in a backbone repeating unit includes a resin containing no maleimide group and having an imide skeleton in a backbone repeating unit.

9. The resin composition according to claim 8,
wherein the resin containing no maleimide group and having an imide skeleton in a backbone repeating unit contains an aliphatic group derived from a dimer diamine.

10. The resin composition according to claim 1, which is thermosetting or photocurable.

11. The resin composition according to claim 1, comprising a compound containing a maleimide group.

12. The resin composition according to claim 11,
wherein the compound containing a maleimide group is a bismaleimide compound or a resin containing a maleimide group and having an imide skeleton in a backbone repeating unit.

13. The resin composition according to claim 12, comprising, as the resin containing a maleimide group and having an imide skeleton in a backbone repeating unit, a resin containing a structural unit represented by the following formula (1) and having a functional group containing a maleimide group at least either at an end or in a side chain: 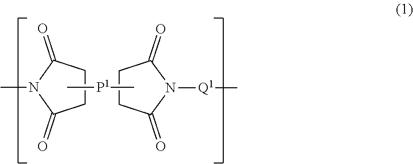
wherein P¹ represents an aromatic group and Q¹ represents a substituted or unsubstituted linear, branched, or cyclic aliphatic group.

14. The resin composition according to claim 1, further comprising a polyfunctional monomer or oligomer containing two or more carbon-carbon double bond-containing reactive functional groups in a molecule and having a molecular weight of 5,000 or less.

15. The resin composition according to claim 14,
wherein the (meth)acrylic copolymer is contained in an amount of 0.1 parts by mass or greater and 20 parts by mass or less relative to 100 parts by mass of a total of the resin having an imide skeleton in a backbone repeating unit and the polyfunctional monomer or oligomer.

16. The resin composition according to claim 1, which is non-curable.

17. The resin composition according to claim 1,
wherein the resin composition has a 10% weight loss temperature of 200 °C or higher.

18. A temporary fixing material comprising the resin composition according to claim 1.

19. A temporary fixing material comprising an adhesive layer containing the resin composition according to claim 1.

20. (canceled)

21. The temporary fixing material according to claim 18,
wherein the temporary fixing material has an initial adhesion to polyimide at 25 °C of 0.1 N/inch or greater and 1.5 N/inch or less.

22. A method for producing an electronic component, the method comprising:
a temporary fixing step of temporarily fixing an electronic component to the temporary fixing material according to claim 18;
a heat treatment step of heat-treating the electronic component; and
a separation step of separating the electronic component from the temporary fixing material.

23. (canceled)
